(19) United States
(12) Patent Application Publication
(10) Pub. No.: US 2023/0387047 A1
(43) Pub. Date: Nov. 30, 2023

(54) SEMICONDUCTOR MODULE

(71) Applicant: Mitsubishi Electric Corporation, Tokyo (JP)

(72) Inventors: Takuma NISHIMURA, Tokyo (JP); Hidenori ISHIBASHI, Tokyo (JP); Toru TAKAHASHI, Tokyo (JP); Yutarou YAMAGUCHI, Tokyo (JP); Takumi NAGAMINE, Tokyo (JP); Kei FUKUNAGA, Tokyo (JP)

(73) Assignee: Mitsubishi Electric Corporation, Tokyo (JP)

(21) Appl. No.: 18/232,978

(22) Filed: Aug. 11, 2023

Related U.S. Application Data
(63) Continuation of application No. PCT/JP2021/009097, filed on Mar. 9, 2021.

(51) Int. Cl. H01L 23/66; H01L 25/18; H01L 23/367; H01L 23/498; H01L 23/00; H01P 3/08; H01P 3/123

(52) U.S. Cl. CPC H01L 23/66; H01L 25/18; H01L 23/367; H01L 23/49822; H01L 24/16; H01P 3/081; H01P 3/123; H01L 2224/16227; H01L 2223/6627; H01L 2924/19032; H01L 2924/1903

(57) ABSTRACT

A semiconductor module includes: a semiconductor element having, on a front face thereof, a signal terminal and a ground terminal; a transmission line body having a signal transmission portion and a ground portion; a signal connection terminal electrically connected to the signal transmission portion of the transmission line body; ground connection terminals arranged to surround the signal connection terminal and electrically connected to the ground portion of the transmission line body, the ground connection terminals and the signal connection terminal constituting a pseudo coaxial line; a heat dissipation plate having a front face in close contact with a back face of the semiconductor element; and an interposer substrate having a semiconductor-element signal pad electrically connected to the signal terminal of the semiconductor element by a conductive adhesive, a transmission-line-body-2 signal pad electrically connected to the signal connection terminal, and a ground portion electrically connected to the ground connection terminals.

### CROSS REFERENCE TO RELATED APPLICATIONS

This application is a Continuation of PCT International Application No. PCT/JP2021/009097 filed on Mar. 9, 2021, which is hereby expressly incorporated by reference into the present application.

### TECHNICAL FIELD

The present disclosure relates to a semiconductor module in which a semiconductor element is mounted on an interposer substrate.

### BACKGROUND ART

Since a semiconductor module used in devices such as those for communication or radar uses a high-frequency signal, flip-chip mounting is under study in which electrical connection of terminals of a semiconductor element is made using a conductive material such as solder bumps in consideration of the influence of parasitic inductance.

For example, Non-Patent Literature 1 discloses a module in which two monolithic microwave integrated circuits (MMICs) are attached to a silicon interposer on the basis of the flip chip technology and the silicon interposer to which the two MMICs are attached is assembled to a printed circuit board (PCB) on the basis of the flip chip technology.

### CITATION LIST

### Non-Patent Literature

Non-Patent Literature 1: Yongrong Shi, Dengyun Shao, Wenjie Feng, Junzhi Zhang, and Ming Zhou, “Silicon Interposer Package for MMIC Heterogeneous Integration Based on Gold/Solder Ball Flip-Chip Technique,” IEEE TRANSACTIONS ON COMPONENTS, PACKAGING AND MANUFACTURING TECHNOLOGY, VOL. 9, NO. 8, Aug. 2019.

### SUMMARY OF INVENTION

### Technical Problem

The module disclosed in Non-Patent Literature 1 has a problem that heat dissipation property to the MMICs is poor since the MMICs are mounted on the silicon interposer on the basis of the flip chip technology.

The present disclosure solves the above problem, and an object of the present disclosure is to obtain a semiconductor module in which a semiconductor element is mounted on an interposer substrate, the semiconductor module having improved heat dissipation property of the semiconductor element.

### Solution to Problem

A semiconductor module according to the present disclosure includes: a semiconductor element having, on a front face thereof, a signal terminal and a ground terminal; a transmission line body having a signal transmission portion and a ground portion; a signal connection terminal having a movable portion at a first end thereof and a fixed portion located at a second end thereof and electrically connected to the signal transmission portion of the transmission line body; a plurality of ground connection terminals arranged to surround the signal connection terminal, each of the ground connection terminals having a movable portion at a first end thereof, and a fixed portion located at a second end thereof and electrically connected to the ground portion of the transmission line body, the plurality of ground connection terminals and the signal connection terminal constituting a pseudo coaxial line; a heat dissipation plate having a front face in close contact with a back face of the semiconductor element; and an interposer substrate having a front face disposed to face the front face of the heat dissipation plate, the interposer substrate having, on the front face, a semiconductor-element signal pad electrically connected to the signal terminal of the semiconductor element by a conductive adhesive, a transmission-line-body signal pad in contact with the movable portion of the signal connection terminal and electrically connected to the signal connection terminal, and a ground portion in contact with the movable portions of the plurality of ground connection terminals and electrically connected to the plurality of ground connection terminals.

### Advantageous Effects of Invention

According to the present disclosure, since a back face of the semiconductor element mounted on the interposer substrate is in close contact with a front face of a heat dissipation plate, the heat dissipation effect of the semiconductor element is improved.

### BRIEF DESCRIPTION OF DRAWINGS

FIG. 1 is a longitudinal cross-sectional view of the main part of a semiconductor module according to a first embodiment.

FIG. 2 is a schematic front view illustrating the main part of a semiconductor element in the semiconductor module according to the first embodiment together with a conductive adhesive.

FIG. 3 is a schematic front view illustrating the main part in another example of the semiconductor element in the semiconductor module of the first embodiment together with a conductive adhesive.

FIG. 4 is a cross-sectional view taken along line I-I of FIG. 3.

FIG. 5 is a schematic front view illustrating the main part of a transmission line body together with a signal connection terminal and a ground connection terminal in the semiconductor module according to the first embodiment.

FIG. 6 is a schematic front view illustrating the main part of an interposer substrate in the semiconductor module according to the first embodiment.

FIG. 7 is a rear view illustrating the interposer substrate in the semiconductor module according to the first embodiment.

FIG. 8 is a schematic front view illustrating the main part in another example of the interposer substrate in the semiconductor module according to the first embodiment.

FIG. 9 is a cross-sectional view taken along line II-II of FIG. 8.

FIG. 10 is a side view illustrating a signal connection terminal and a ground connection terminal in the semiconductor module according to the first embodiment.

FIG. 11 is another schematic front view illustrating the main part of the transmission line body together with the signal connection terminal and the ground connection terminal in the semiconductor module according to the first embodiment.

FIG. 12 is a side view illustrating another example of the signal connection terminal and the ground connection terminal in the semiconductor module according to the first embodiment.

FIG. 13 is a longitudinal cross-sectional view of the main part of a semiconductor module according to a second embodiment.

FIG. 14 is a longitudinal cross-sectional view of the main part of a semiconductor module according to a third embodiment.

FIG. 15 is an enlarged longitudinal cross-sectional view of the main part of FIG. 14.

FIG. 16 is a schematic front view illustrating the main part of a transmission line body together with a signal connection terminal and a ground connection terminal in the semiconductor module according to the third embodiment.

FIG. 17 is a schematic rear view illustrating the main part of the transmission line body together with the signal connection terminal in the semiconductor module according to the third embodiment.

FIG. 18 is a front view of the main part of a heat dissipation plate in the semiconductor module according to the third embodiment.

FIG. 19 is a longitudinal cross-sectional view of the main part of a semiconductor module according to a fourth embodiment.

FIG. 20 is a schematic front view illustrating the main part of a transmission line body in a semiconductor module according to a fifth embodiment.

FIG. 21 is a longitudinal cross-sectional view of the main part of a semiconductor module according to a sixth embodiment.

FIG. 22 is a schematic front view illustrating the main part of a spacer in the semiconductor module according to the sixth embodiment.

FIG. 23 is a longitudinal cross-sectional view of the main part of a semiconductor module according to a seventh embodiment.

FIG. 24 is an enlarged longitudinal cross-sectional view of the main part of FIG. 23.

FIG. 25 is a schematic front view illustrating the main part of a transmission line body together with a ground connection terminal in the semiconductor module according to the seventh embodiment.

FIG. 26 is a cross-sectional view taken along line in a transmission line body of FIG. 23.

FIG. 27 is a cross-sectional view taken along line illustrating another example of the transmission line body in the semiconductor module according to the seventh embodiment.

FIG. 28 is a cross-sectional view taken along line illustrating still another example of the transmission line body in the semiconductor module according to the seventh embodiment.

FIG. 29 is a longitudinal cross-sectional view of the main part of a semiconductor module according to an eighth embodiment.

FIG. 30 is a front view illustrating a conductor plate in the semiconductor module according to the eighth embodiment.

FIG. 31 is a front view illustrating another example of the conductor plate in the semiconductor module according to the eighth embodiment.

FIG. 32 is a longitudinal cross-sectional view of the main part of a semiconductor module according to a ninth embodiment.

FIG. 33 is a front view illustrating a heat dissipation plate in the semiconductor module according to the ninth embodiment.

FIG. 34 is a schematic rear view illustrating the main part of a transmission line body in the semiconductor module according to the ninth embodiment.

FIG. 35 is a longitudinal cross-sectional view of the main part of a semiconductor module according to a tenth embodiment.

FIG. 36 is an enlarged longitudinal cross-sectional view of the main part of FIG. 35.

FIG. 37 is a schematic front view illustrating the main part of a transmission line body in the semiconductor module according to the tenth embodiment.

FIG. 38 is a longitudinal cross-sectional view of the main part of a semiconductor module according to an eleventh embodiment.

FIG. 39 is a right side view orthogonal to FIG. 30, illustrating the main part of the semiconductor module according to the eleventh embodiment.

FIG. 40 is a transverse cross-sectional view illustrating a conductor side wall of a transmission line body in the semiconductor module according to the eleventh embodiment.

FIG. 41 is a schematic front view illustrating the main part of a conductor upper wall of the transmission line body together with a ground connection terminal in the semiconductor module according to the eleventh embodiment.

FIG. 42 is a schematic front view illustrating the main part of another example of the conductor upper wall of the transmission line body together with the ground connection terminal in the semiconductor module according to the eleventh embodiment.

FIG. 43 is a longitudinal cross-sectional view of the main part of a semiconductor module according to a twelfth embodiment.

FIG. 44 is a schematic front view illustrating the main part of a conductor upper wall of a transmission line body in the semiconductor module according to the twelfth embodiment.

FIG. 45 is a schematic front view illustrating the main part of another example of the conductor upper wall of the transmission line body in the semiconductor module according to the twelfth embodiment.

FIG. 46 is a longitudinal cross-sectional view of the main part of a semiconductor module according to a thirteenth embodiment.

FIG. 47 is a right side view orthogonal to FIG. 30, illustrating the main part of the semiconductor module according to the thirteenth embodiment.

FIG. 48 is a longitudinal cross-sectional view of the main part of a semiconductor module according to a fourteenth embodiment.

FIG. 49 is a cross-sectional view taken along line IV-IV illustrating a part as a waveguide path of a heat dissipation plate in the semiconductor module according to the fourteenth embodiment.

FIG. 50 is a longitudinal cross-sectional view of the main part of a semiconductor module according to a fifteenth embodiment.

FIG. 51 is a schematic front view illustrating the main part of a side wall body in the semiconductor module according to the fifteenth embodiment.

FIG. 52 is a cross-sectional view taken along line V-V of FIG. 51.

FIG. 53 is a longitudinal cross-sectional view of the main part of a semiconductor module according to a sixteenth embodiment.

FIG. 54 is a cross-sectional view corresponding to FIG. 52, illustrating the main part of a side wall body in the semiconductor module according to the sixteenth embodiment.

FIG. 55 is a longitudinal cross-sectional view of the main part of a semiconductor module according to a seventeenth embodiment.

FIG. 56 is a schematic front view illustrating the main part of an interposer substrate in the semiconductor module according to the seventeenth embodiment.

FIG. 57 is a schematic front view of the interposer substrate illustrated in FIG. 56 on which a first high-frequency power-amplification semiconductor element to a fourth high-frequency power-amplification semiconductor element are mounted.

FIG. 58 is a schematic front view illustrating the main part of a transmission line body in the semiconductor module according to the seventeenth embodiment.

FIG. 59 is a cross-sectional view taken along line VI-VI in the transmission line body of FIG. 55.

### DESCRIPTION OF EMBODIMENTS

### First Embodiment

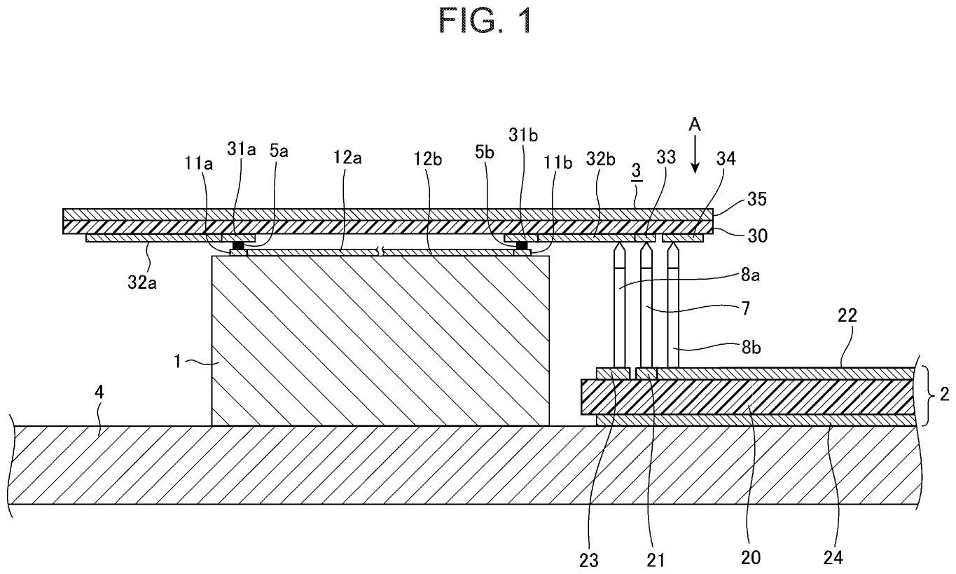

A semiconductor module according to a first embodiment will be described with reference to FIGS. 1 to 12.

A high-frequency amplifier module will be described as an example of the semiconductor module.

As illustrated in FIG. 1, the semiconductor module includes a semiconductor element 1, a transmission line body 2, an interposer substrate 3, and a heat dissipation plate 4.

The semiconductor element 1 is a high-frequency high-power amplifier.

Note that a high-frequency high-power amplifier will be described as an example of the semiconductor element 1, however, a power amplifier on which a plurality of active elements such as transistors is mounted or a semiconductor integrated circuit device (IC) on which a plurality of passive components is mounted may be used as the semiconductor element 1.

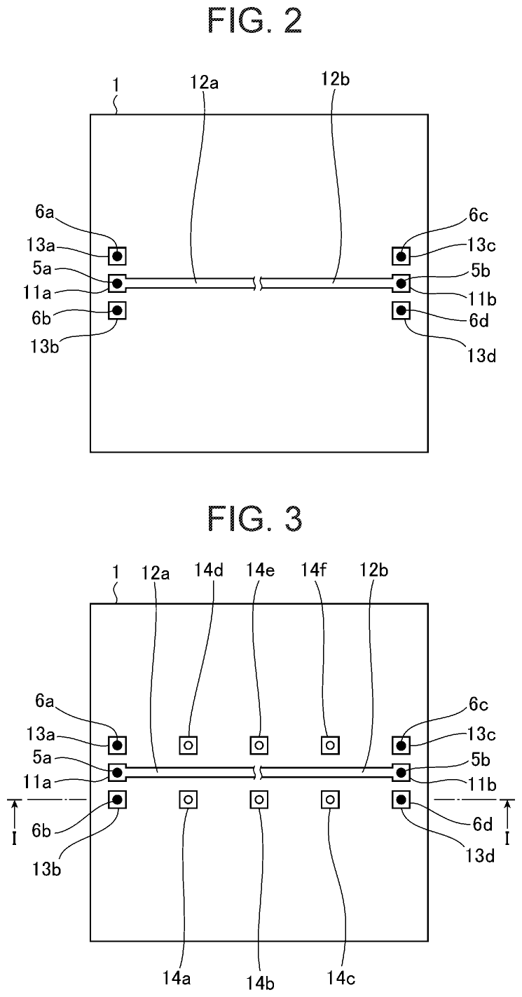

As illustrated in FIG. 2, the semiconductor element 1 has two signal terminals on a front face, that is, an input signal terminal 11a and an output signal terminal 11b, an input signal line 12a connected to the input signal terminal 11a, an output signal line 12b connected to the output signal terminal 11b, and four ground terminals 13a to 13d.

The two signal terminals 11a and 11b, the two signal lines 12a and 12b, and the four ground terminals 13a to 13d are conductor layers formed on an insulating film formed on a front face of a semiconductor substrate by vapor deposition or the like and patterned.

The input signal terminal 11a is disposed at a first side end of the front face of the semiconductor substrate, and the output signal terminal 11b is disposed at a second side end of the front face of the semiconductor substrate.

The two ground terminals 13a and 13b are arranged along the first side end of the front face of the semiconductor substrate, and the input signal terminal 11a is between the ground terminals 13a and 13b. The two ground terminals 13c and 13d are arranged along the second side end of the front face of the semiconductor substrate, and the output signal terminal 11b is between the ground terminals 13c and 13d.

A ground layer (not illustrated) may be formed on the entire back face of the semiconductor element 1.

Note that the two signal lines 12a and 12b formed on the front face of the semiconductor element 1 are not limited to straight lines and may have curves, branches, or others.

In addition, the number of ground terminals 13a to 13d is not limited to four and may be five or more.

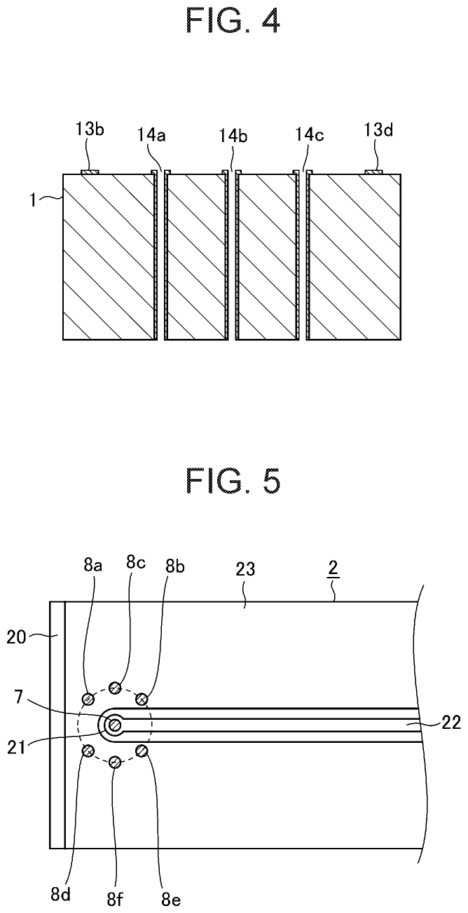

Furthermore, as illustrated in FIGS. 3 and 4, the semiconductor element 1 may have a plurality of vias 14a to 14f formed on the semiconductor substrate included in the semiconductor element 1 in order to prevent electrical interference with other signal lines (not illustrated) on both sides of the two signal lines 12a and 12b.

The plurality of vias 14a to 14f may be vias conforming to specifications such as through-vias or filling lid-plated vias.

In addition, since the semiconductor element 1 is a high-frequency high-power amplifier, the two signal lines 12a and 12b are regarded as the input signal line 12a and the output signal line 12b, respectively. However, in a case where the semiconductor element 1 is a power amplifier having a plurality of active elements mounted thereon or a semiconductor integrated circuit device having a plurality of passive components mounted thereon, it has two or more signal lines that transmit two or more high-frequency signals.

In this case, it is also possible to similarly apply to three or more signal lines and three or more signal terminals connected thereto.

The transmission line body 2 is a microstrip line that has a dielectric substrate 20, a signal transmission line 22 formed on a front face of the dielectric substrate 20, and a ground layer 24 formed on a back face of the dielectric substrate 20 and transmits an electromagnetic wave that is a high-frequency signal.

As illustrated in FIG. 5, the transmission line body 2 includes a signal transmission portion 21, a signal transmission line 22, and a ground portion 23 on the front face of the dielectric substrate 20.

The signal transmission portion 21 is a signal pad formed on the front face of the dielectric substrate 20 included in the transmission line body 2 and is connected to the signal transmission line 22 formed on the front face of the dielectric substrate.

The signal transmission line 22 transmits a high-frequency signal input to a signal pad 21.

The signal transmission line 22 functions as a transmission line of a microstrip line.

The ground portion 23 is a ground conductor formed on the front face of the dielectric substrate 20 and electrically separated from the signal pad 21 and the signal transmission line 22.

The signal pad 21, the signal transmission line 22, and the ground portion 23 are conductor layers formed on the front face of the dielectric substrate 20 by vapor deposition or the like and patterned.

A ground layer 24 made of a ground conductor is formed on the entire back face of the transmission line body 2.

Note that the transmission line body 2 may include a multilayer substrate depending on specifications.

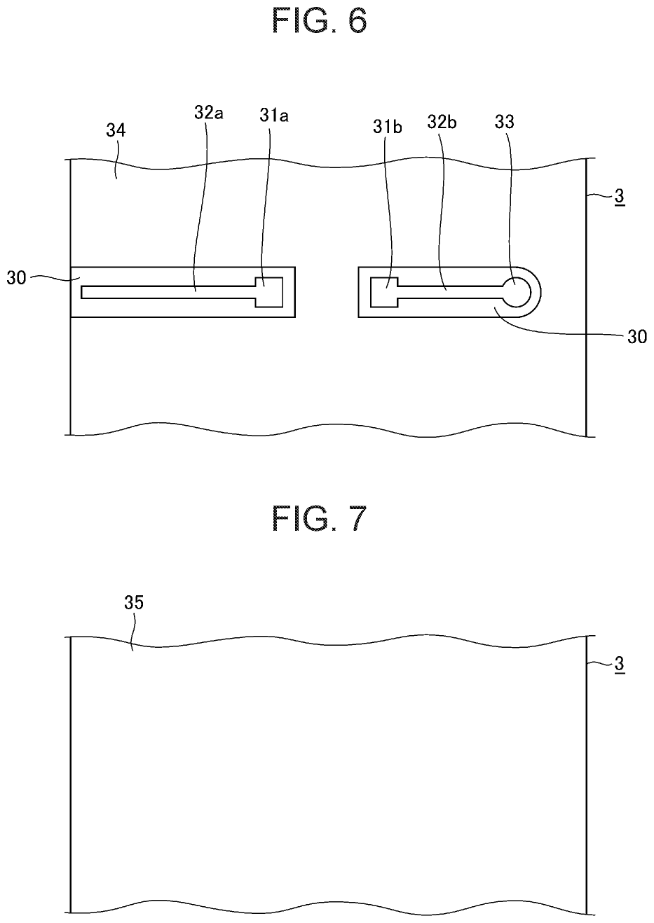

As illustrated in FIG. 6, the interposer substrate (relay wiring board) 3 has two semiconductor-element signal pads, that is, an input-side semiconductor-element signal pad 31a and an output-side semiconductor-element signal pad 31b, an input-side signal line 32a connected to the input-side semiconductor-element signal pad 31a, an output-side signal line 32b connected to the output-side semiconductor-element signal pad 31b, a transmission-line-body signal pad 33 connected to the output-side signal line 32b, and a ground portion 34 which is a ground conductor on the front face of the dielectric substrate 30 and has a ground layer 35 which is a ground conductor on the back face of the dielectric substrate 30.

As illustrated in FIGS. 1 and 2, the input-side semiconductor-element signal pad 31a is electrically connected to the input signal terminal 11a of the semiconductor element 1 by a conductive adhesive 5a such as a solder ball.

As illustrated in FIGS. 1 and 2, the output-side semiconductor-element signal pad 31b is electrically connected to the output signal terminal 11b of the semiconductor element 1 by a conductive adhesive 5b such as a solder ball.

Each of the input-side signal line 32a and the output-side signal line 32b functions as a transmission line of a microstrip line.

The ground portion 34 is a ground conductor electrically separated from the input-side semiconductor-element signal pad 31a, the output-side semiconductor-element signal pad 31b, the input-side signal line 32a, the output-side signal line 32b, and the transmission-line-body signal pad 33.

The input-side semiconductor-element signal pad 31a, the output-side semiconductor-element signal pad 31b, the input-side signal line 32a, the output-side signal line 32b, the transmission-line-body signal pad 33, and the ground portion 34 are conductor layers formed and patterned by vapor deposition or the like on the front faces of the dielectric substrate 30 such as a silicon substrate, a resin substrate, or a glass substrate having high resistance, that is, insulation.

As illustrated in FIG. 2, the ground portion 34 is electrically connected to the ground terminals 13a to 13d formed on the front face of the semiconductor element 1 by conductive adhesives 6a to 6d, respectively, such as solder balls.

The conductive adhesives 6a to 6d are made of the same material as that of the conductive adhesives 5a and 5b.

The semiconductor element 1 is flip-chip mounted on a front face of the interposer substrate 3 by using the conductive adhesives 5a and 5b and the conductive adhesives 6a to 6d.

Note that the planar shapes of the input signal terminal 11a, the output signal terminal 11b, and the ground terminals 13a to 13d formed on the front face of the semiconductor element and the planar shapes of the input-side semiconductor-element signal pad 31a and the output-side semiconductor-element signal pad 31b formed on the front face of the interposer substrate 3 are not limited to rectangular shapes but may be other shapes such as circular shapes as long as desired electrical characteristics can be achieved in electrical connection using the conductive adhesives 5a and 5b and the conductive adhesives 6a to 6d.

As illustrated in FIG. 7, in the interposer substrate 3, the ground layer 35 is formed on the entire back face of the dielectric substrate 30.

The ground portion 34 formed on the front face of the dielectric substrate 30 and the ground layer 35 formed on the back face of the dielectric substrate 30 are electrically connected by a via hole formed in the dielectric substrate 30.

When the front face of the interposer substrate 3 on which the semiconductor element 1 is mounted is disposed to face the front face of the heat dissipation plate 4, the transmission-line-body signal pad 33 is disposed at a position facing the signal transmission portion 21 formed on the front face of the transmission line body 2.

The transmission-line-body signal pad 33 and the signal transmission portion 21 are electrically connected by the signal connection terminal 7.

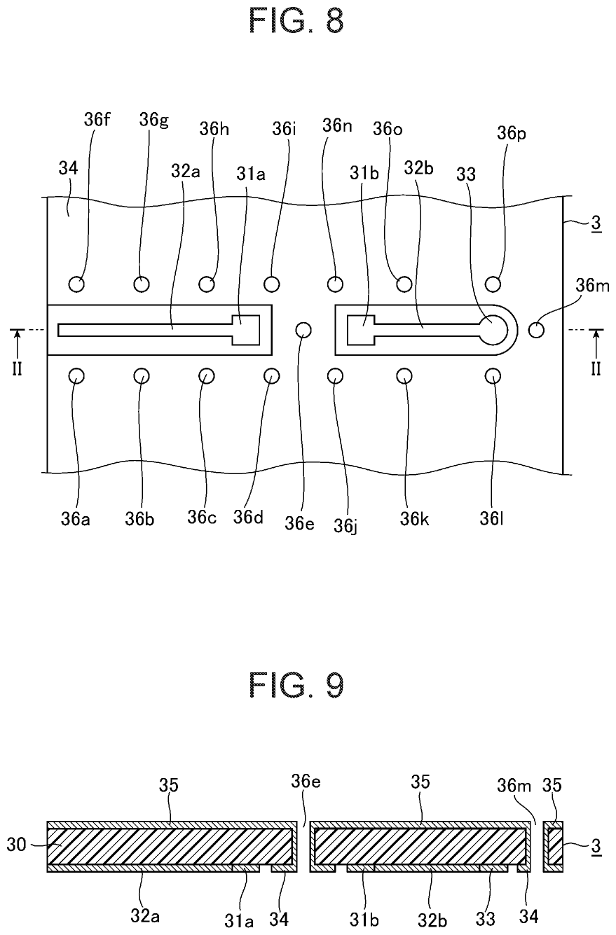

Note that, as illustrated in FIGS. 8 and 9, the interposer substrate 3 may have a plurality of vias 36a to 36p formed in the dielectric substrate 30 to surround each of the input-side signal line 32a and the output-side signal line 32b to prevent electrical interference with other signal lines (not illustrated).

The plurality of vias 36a to 36p may be vias conforming to specifications such as through-vias or filling lid-plated vias.

Meanwhile, the interposer substrate 3 may be a multilayer substrate depending on specifications.

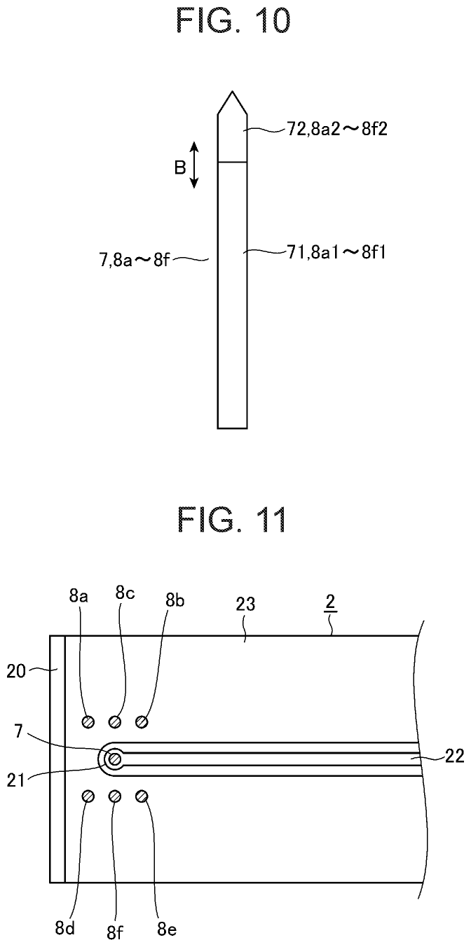

As illustrated in FIG. 10, the signal connection terminal 7 is a spring structure terminal, such as a spring probe, having a fixed portion 71 and a movable portion 72 at a distal end and as illustrated by an arrow B, the movable portion 72 extends and contracts in the up-down direction in the drawing with respect to the fixed portion 71.

As illustrated in FIG. 5, in the signal connection terminal 7, a rear end of the fixed portion 71 located at a second end is electrically and mechanically connected to the signal transmission portion 21 formed on a front face of the transmission line body 2.

In the signal connection terminal 7, the movable portion 72 located at a first end protrudes from the front face of the transmission line body 2.

When the front face of the interposer substrate 3 on which the semiconductor element 1 is mounted is disposed to face the front face of the heat dissipation plate 4, the distal end of the movable portion 72 of the signal connection terminal 7 is pressed in contact with the transmission-line-body signal pad 33 formed on the front face of the interposer substrate 3, and the movable portion 72 of the signal connection terminal 7 moves toward the fixed portion 71.

As a result, the transmission-line-body signal pad 33 is brought into close contact with the distal end of the movable portion 72 of the signal connection terminal 7 in a state where pressure is applied to the distal end.

Note that the planar shape of the transmission-line-body signal pad 33 is not limited to a circular shape and may be another shape such as a square shape as long as desired electrical characteristics can be implemented in electrical connection with the distal end of the movable portion 72 of the signal connection terminal 7.

A plurality of ground connection terminals 8a to 8f is arranged to surround the signal connection terminal 7 and, together with the signal connection terminal 7, constitute a pseudo coaxial line.

Each of the plurality of ground connection terminals 8a to 8f has the same structure as that of the signal connection terminal 7 and is a spring structure terminal such as a spring probe having fixed portions 8a1 to 8f1 and movable portions 8a2 to 8f2 at distal ends as illustrated in FIG. 10. As illustrated by the arrow B, the movable portions 8a2 to 8f2 extend and contract in the up-down direction in the drawing with respect to the fixed portions 8a1 to 8f1.

As illustrated in FIGS. 1 and 5, the plurality of ground connection terminals 8a to 8f is arranged concentrically around the signal connection terminal 7 to surround the signal connection terminal 7, and rear ends of the fixed portions 8a1 to 8f1 located at second ends are electrically and mechanically connected to the ground portion 23 formed on the front face of the transmission line body 2.

In the plurality of ground connection terminals 8a to 8f, the movable portions 8a2 to 8f2 located at first ends protrude from the front face of the transmission line body.

When the front face of the interposer substrate 3 on which the semiconductor element 1 is mounted is disposed to face the front face of the heat dissipation plate 4, distal ends of the movable portions 8a2 to 8f2 of the plurality of ground connection terminals 8a to 8f, respectively, are pressed in contact with the ground portion 34 formed on the front face of the interposer substrate 3, and the movable portions 8a2 to 8f2 of the plurality of ground connection terminals 8a to 8f move toward the fixed portions 8a1 to 8f1, respectively.

As a result, the ground portion 34 is brought into close contact with the distal ends of the movable portions 8a2 to 8f2 of the plurality of ground connection terminals 8a to 8f, respectively, in a state where pressure is applied to the distal ends.

Note that it is only required that the distal end of the movable portion 72 of the signal connection terminal 7 can be electrically connected to the transmission-line-body signal pad 33 and that the distal ends of the movable portions 8a2 to 8f2 of the ground connection terminals 8a to 8f can be electrically connected to the ground portion 34, and the distal end of the movable portion 72 of the signal connection terminal 7 and the distal ends of the movable portion 8a2 to 8f2 of the ground connection terminals 8a to 8f may have any shape such as a flat shape or a circular shape.

The number of the ground connection terminals 8a to 8f is not limited to six, and may be six or more or six or less depending on the purpose such as improvement in mounting, downsizing, and electrical interference between the input-side signal line 32a and the output-side signal line 32b, and other signal lines.

In addition, the ground connection terminals 8a to 8f may be in any arrangement as long as the pseudo coaxial line by the signal connection terminal 7 and the ground connection terminals 8a to 8f has a desired characteristic impedance and, as illustrated in FIG. 11, may be arranged on linear lines on both sides of the signal connection terminal 7.

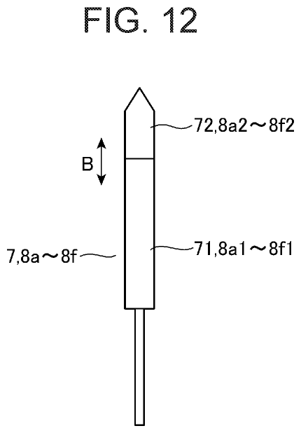

Furthermore, as illustrated in FIG. 12, in the signal connection terminal 7 and the ground connection terminals 8a to 8f, the fixed portions 71 and 8a1 to 8f1 may have a small diameter portion F2 having a smaller diameter than a spring mechanism housing portion F1 located on the movable portions 72 and 8a2 to 8f2 side.

As illustrated in FIG. 1, the back face of the semiconductor element 1 and the back face of the transmission line body 2 are in close contact with the front face of the heat dissipation plate 4.

As the heat dissipation plate 4, a metal plate having a high heat dissipation effect is used.

In the semiconductor module according to the first embodiment configured as described above, first, the semiconductor element 1 is flip-chip mounted on the front face of the interposer substrate 3 using the conductive adhesives 5a and 5b and the conductive adhesives 6a to 6d.

Next, the interposer substrate 3 on which the semiconductor element 1 is mounted is disposed so that the front face thereof faces the front face of the heat dissipation plate 4, and the interposer substrate 3 is pressed against the heat dissipation plate 4 from the direction of the arrow A illustrated in FIG. 1 so that the back face of the semiconductor element 1 is brought into close contact with the front face of the heat dissipation plate 4.

At this point, the transmission-line-body signal pad 33 formed on the front face of the interposer substrate 3 is pressed against the distal end of the movable portion 72 of the signal connection terminal 7 connected to the signal transmission portion 21 formed on the front face of the transmission line body 2, and simultaneously the ground portion 34 formed on the front face of the interposer substrate 3 is pressed against the distal end of the movable portions 8a2 to 8f2 of the ground connection terminals 8a to 8f connected to the ground portion 23 formed on the front face of the transmission line body 2.

As a result, the output signal line 12b formed on the front face of the semiconductor element 1 and a transmission path for a high-frequency signal, which extends from the output signal terminal 11b to the signal transmission portion 21 and the signal transmission line 22 formed on the front face of the transmission line body 2 via the output-side semiconductor-element signal pad 31b, the output-side signal line 32b, and the transmission-line-body signal pad 33 formed on the front face of the interposer substrate 3, are electrically connected to each other by the conductive adhesive 5b and the signal connection terminal 7.

That is, the high-frequency signal transmitted through the output signal line 12b of the semiconductor element 1 is input from the output signal terminal 11b of the semiconductor element 1 to the output-side semiconductor-element signal pad 31b of the interposer substrate 3, transmitted through the output-side signal line 32b of the interposer substrate 3, input from the transmission-line-body signal pad 33 to the signal transmission portion 21 of the transmission line body 2 via the pseudo coaxial line including the signal connection terminal 7 and the plurality of ground connection terminals 8a to 8f, and transmitted through the signal transmission line 22.

As described above, in the semiconductor module according to the first embodiment, the semiconductor element 1 is flip-chip mounted on the interposer substrate 3, and connection between the input signal terminal 11a and the output signal terminal 11b of the semiconductor element 1 and the input-side semiconductor-element signal pad 31a and the output-side semiconductor-element signal pad 31b of the interposer substrate 3, respectively, and connection between the ground terminals 13a to 13d of the semiconductor element 1 and the ground portion 34 of the interposer substrate 3 are made by the conductive adhesives 5a, 5b, and 6a to 6d, and the conductive adhesives 5a, 5b, and 6a to 6d are small, and the mounting tolerance is also small. Therefore, the influence of parasitic inductance and deterioration of electrical characteristics can be reduced.

In addition, in the semiconductor module according to the first embodiment, the transmission-line-body signal pad 33 of the interposer substrate 3 and the signal transmission portion 21 of the transmission line body 2 are connected by the signal connection terminal 7 having the movable portion that expands and contracts with respect to the fixed portion, and the ground portion 34 of the interposer substrate 3 and the ground portion 23 of the transmission line body 2 are arranged and connected to surround the signal connection terminal 7 by the plurality of ground connection terminals 8a to 8f each having a movable portion that expands and contracts with respect to a fixed portion, and the pseudo coaxial line constituted by the signal connection terminal 7 and the plurality of ground connection terminals 8a to 8f includes connection terminals having movable portions. Therefore, it is possible to surely assemble the semiconductor element 1 and the transmission line body 2 even in a case where there is a tolerance, namely, a level difference, in the thickness direction thereof, thereby ensuring electrical connection and enabling reliable transmission of a high-frequency signal.

Furthermore, in the semiconductor module according to the first embodiment, even in a case where there is a tolerance, namely, a level difference in the thickness direction between the semiconductor element 1 and the transmission line body 2, since the signal connection terminal 7 and the plurality of ground connection terminals 8a to 8f absorb the level difference, the interposer substrate 3 on which the semiconductor element 1 is mounted can be pressed against the heat dissipation plate 4, the back face of the semiconductor element 1 and the back face of the transmission line body 2 can be brought into close contact with the front face of the heat dissipation plate 4, the interposer substrate 3 and the transmission line body 2 can be stably mounted on the heat dissipation plate 4 with the semiconductor element 1 mounted on the interposer substrate 3, thermal resistance between the back face of the semiconductor element 1 and the front face of the heat dissipation plate 4 can be reduced, and heat generated by the semiconductor element 1 can be dissipated by the heat dissipation plate 4 efficiently.

### Second Embodiment

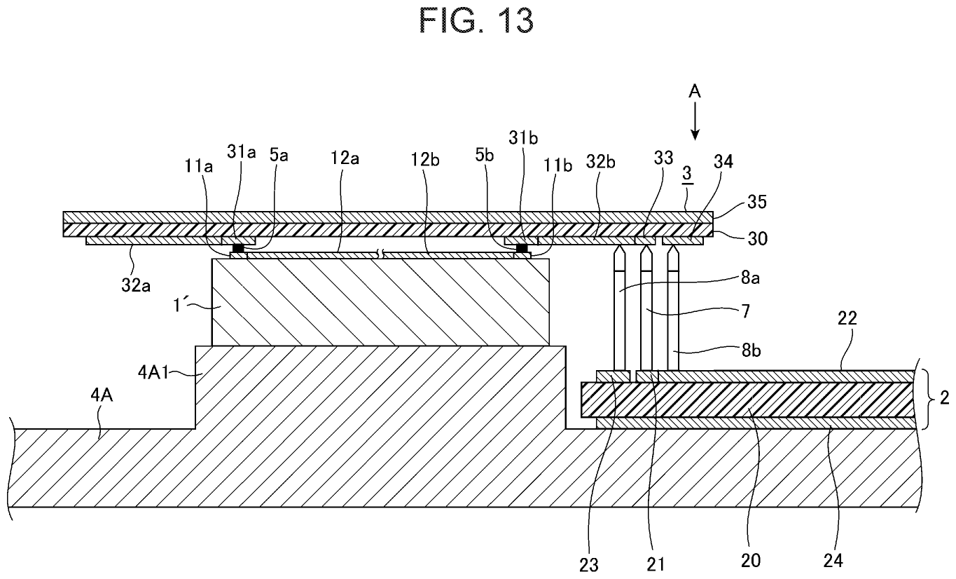

A semiconductor module according to a second embodiment will be described with reference to FIG. 13.

The semiconductor module according to the second embodiment is an embodiment obtained by applying a semiconductor element 1′ obtained by reducing the thickness of the semiconductor element 1 to the semiconductor module according to the first embodiment and uses a heat dissipation plate 4A having a protrusion 4A1 at a position corresponding to the semiconductor element 1′.

That is, in the heat dissipation plate 4A, the protrusion 4A1 is formed at a portion where a back face of the semiconductor element 1′ is in close contact.

The semiconductor module according to the second embodiment is different from the semiconductor module according to the first embodiment only in the thickness of the semiconductor element 1′ and the heat dissipation plate 4A having the protrusion 4A1, and the other components are the same.

Note that in FIG. 13 the same symbols as those in FIG. 1 denote the same or corresponding parts.

The semiconductor module according to the second embodiment also achieves similar effects to those of the semiconductor module according to the first embodiment.

### Third Embodiment

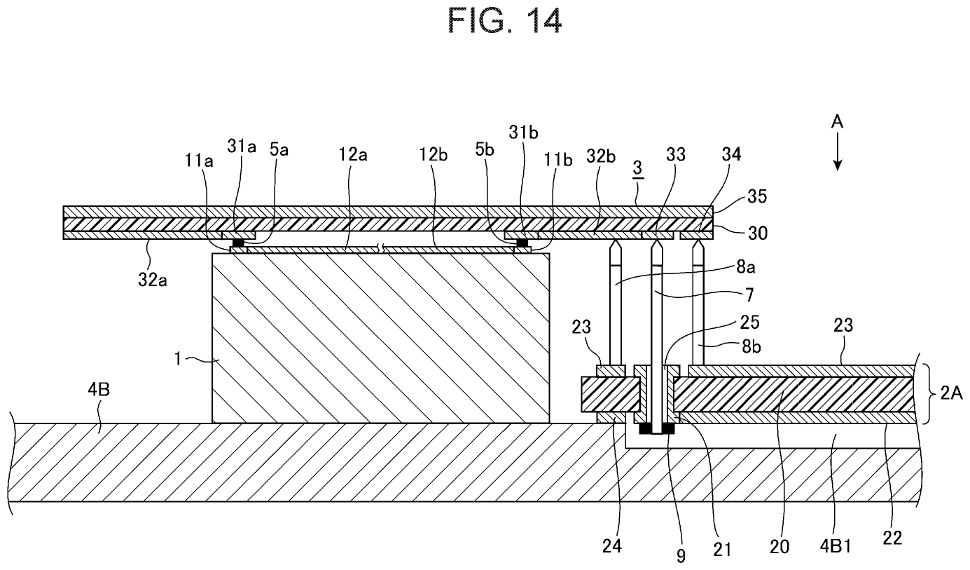

A semiconductor module according to a third embodiment will be described with reference to FIGS. 14 to 18.

The semiconductor module according to the third embodiment is different from the semiconductor module according to the first embodiment in the following points, and the other components are the same.

Note that in FIGS. 14 to 18, the same symbols as those in the drawings used for description of the first embodiment denote the same or corresponding parts.

That is, the transmission line body 2 in the semiconductor module according to the first embodiment has the signal pad, namely, the signal transmission portion 21 and the signal transmission line 22 to which the signal transmission portion 21 is connected on the front face of the dielectric substrate, whereas a transmission line body 2A in the semiconductor module according to the third embodiment is different in that a signal transmission portion 21 and a signal transmission line 22 are provided on a back face of a dielectric substrate and that, on the basis of this difference, the signal transmission portion 21 and the signal connection terminal 7 are connected and a recessed portion 4B1 is included in a front face of the heat dissipation plate 4B to which the signal transmission portion 21 corresponds.

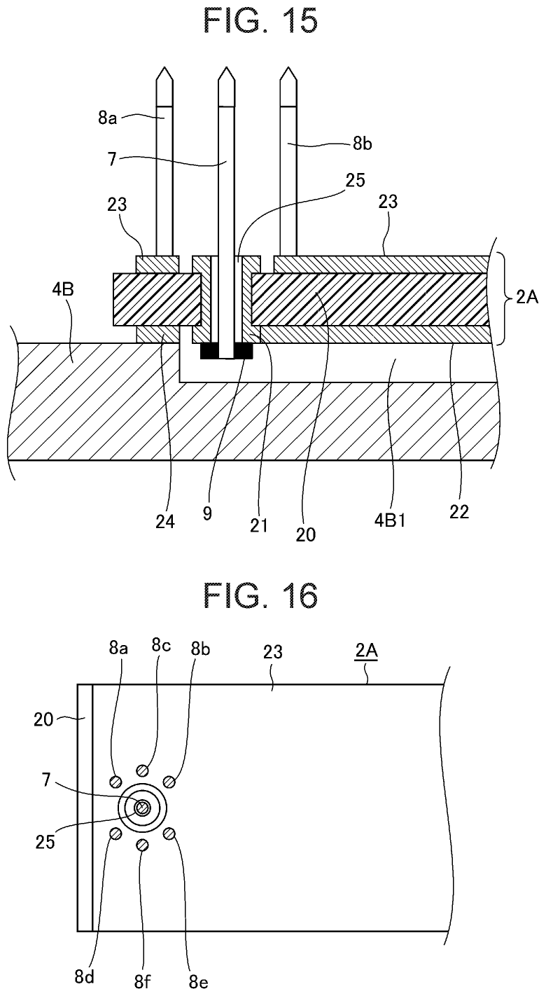

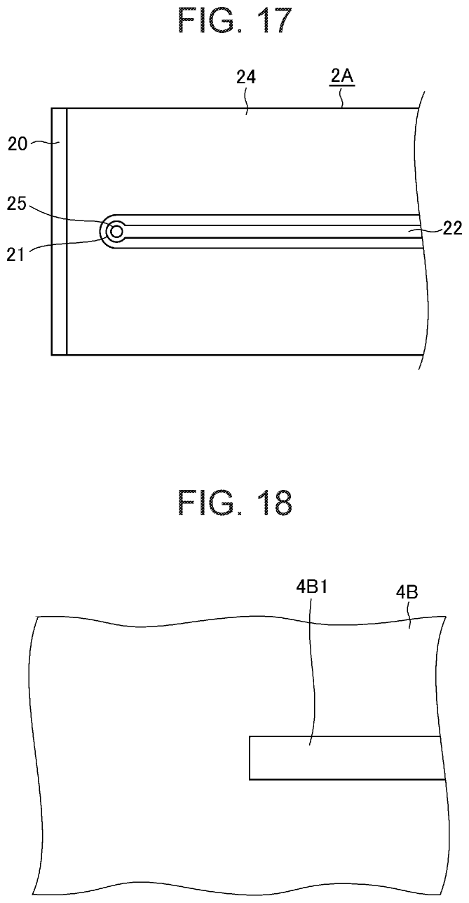

As illustrated in FIG. 16, the transmission line body 2A includes a ground layer 23 on a front face of the dielectric substrate included in the transmission line body 2 and includes on the back face of the dielectric substrate, as illustrated in FIG. 17, the signal transmission portion 21 which is a signal pad, the signal transmission line 22 which is connected to the signal transmission portion 21 and transmits a high-frequency signal input to the signal transmission portion 21, and a ground portion 24 formed and electrically separated from the signal transmission portion 21 and the signal transmission line 22, the ground portion 24 made of a ground conductor, and as illustrated in FIGS. 14 to 17, a through-via 25 into which the signal connection terminal 7 is inserted is formed in the dielectric substrate.

The signal transmission portion 21, the signal transmission line 22, and the ground portion 24 are conductor layers formed on the back face of the dielectric substrate by vapor deposition or the like and patterned.

A land of the through-via 25 that is formed on the front face of the dielectric substrate is formed and electrically separated from the ground layer 23.

As illustrated in FIGS. 14 to 17, in the signal connection terminal 7, a rear end of a fixed portion 71 located at a second end thereof is inserted through the through-via 25, and the signal connection terminal 7 is electrically and mechanically connected to the signal transmission portion 21 formed on the back face of the transmission line body 2A by a conductive adhesive 9 such as solder at a rear end thereof.

In addition, the signal connection terminal 7 may be electrically and mechanically connected to the land of the through-via 25 formed on the front face of the dielectric substrate at the rear end of the fixed portion 71.

As illustrated in FIGS. 14 to 16, similarly to the ground connection terminals 8a to 8f in the semiconductor module according to the first embodiment, a plurality of ground connection terminals 8a to 8f is arranged to surround the signal connection terminal 7 and, together with the signal connection terminal 7, form a pseudo coaxial line, and rear ends of fixed portions 8a1 to 8f1 located at second ends are electrically and mechanically connected to the ground layer 23 formed on the front face of the transmission line body 2A.

As illustrated in FIGS. 14, 15, and 18, the heat dissipation plate 4B includes the recessed portion 4B1 physically separated from the signal transmission portion 21 and the signal transmission line 22 of the transmission line body 2A on the front face to which the signal transmission portion 21 and the signal transmission line 22 of the transmission line body 2A face.

The ground portion 24 formed on the back face of the transmission line body 2A is in close contact with the front face of the heat dissipation plate 4B.

The semiconductor module according to the third embodiment also achieves similar effects to those of the semiconductor module according to the first embodiment.

### Fourth Embodiment

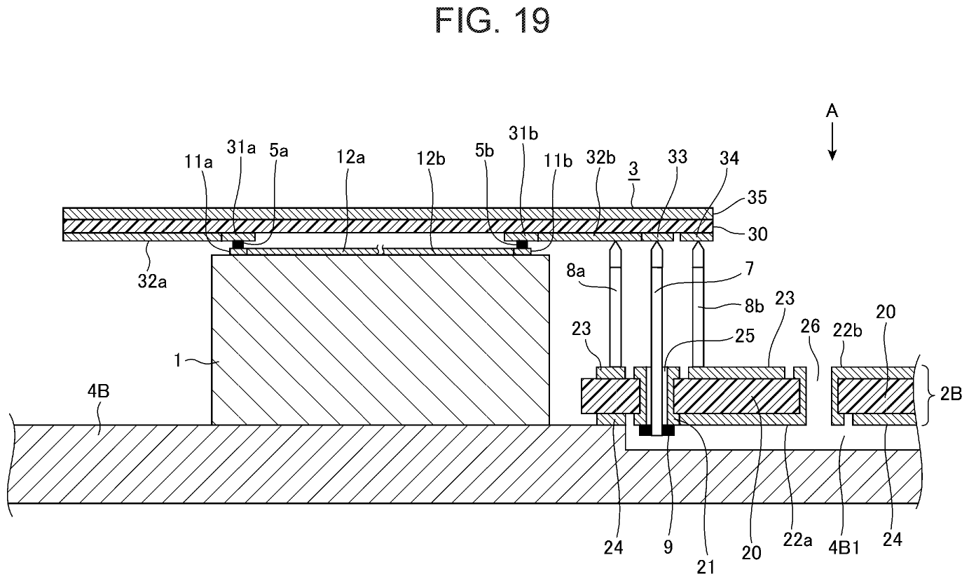

A semiconductor module according to a fourth embodiment will be described with reference to FIG. 19.

The semiconductor module according to the fourth embodiment is different from the semiconductor module according to the third embodiment in the following points, and the other components are the same.

Note that in FIG. 19 the same symbols as those in FIG. 14 denote the same or corresponding parts.

That is, a transmission line body 2B in the semiconductor module according to the fourth embodiment is different from the transmission line body 2A in the semiconductor module according to the third embodiment in that a signal transmission line 22b, electrically connected to a signal transmission line 22a formed on a back face of a dielectric substrate via a through-via 26 formed in the dielectric substrate, is further formed on a front face of the dielectric substrate.

The signal transmission line 22b and a land of the through-via 26 formed on the front face of the dielectric substrate are formed and electrically separated from a ground portion 23.

The signal transmission line 22b and the ground portion 23 are conductor layers formed on the front face of the dielectric substrate by vapor deposition or the like and patterned.

Note that the through-via 26 is not limited to a through-via and may be a via conforming to specifications such as a filling lid-plated via.

The semiconductor module according to the fourth embodiment also achieves similar effects to those of the semiconductor module according to the third embodiment.

### Fifth Embodiment

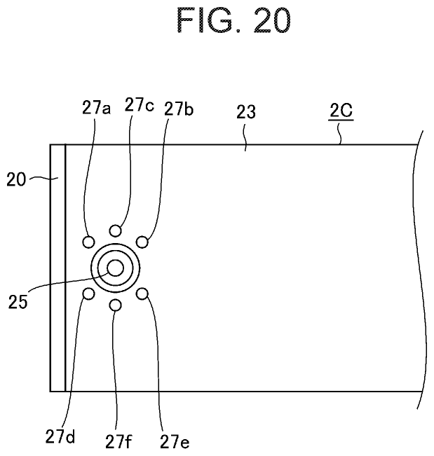

A semiconductor module according to a fifth embodiment will be described with reference to FIG. 20.

The semiconductor module according to the fifth embodiment is different from the semiconductor module according to the third embodiment in the following points, and the other components are the same.

Note that in FIG. 20 the same symbols as those in FIG. 16 denote the same or corresponding parts.

That is, a transmission line body 2C in the semiconductor module according to the fifth embodiment is different from the transmission line body 2A in the semiconductor module according to the third embodiment in that a plurality of through-vias 27a to 27f is formed in correspondence to a plurality of ground connection terminals 8a to 8f.

Although not illustrated, in the plurality of ground connection terminals 8a to 8f, similarly to the case where the rear end of the fixed portion 71 of the signal connection terminal 7 in the semiconductor module according to the third embodiment is inserted through the through-via 25 and electrically and mechanically connected to the signal transmission portion 21 formed on the back face of the transmission line body 2A by a conductive adhesive such as solder at the rear end, rear ends of fixed portions 8a1 to 8f1 are inserted through corresponding through-vias 27a to 27f, respectively, and the plurality of the ground connection terminals 8a to 8f is electrically and mechanically connected to a ground layer 24 formed on a back face of the transmission line body 2C by a conductive adhesive such as solder at rear ends thereof.

In addition, the plurality of ground connection terminals 8a to 8f may be electrically and mechanically connected to lands of the through-vias 27a to 27f formed on the front face of the dielectric substrate at the rear ends of the fixed portions 8a1 to 8f1, respectively.

The semiconductor module according to the fifth embodiment also achieves similar effects to those of the semiconductor module according to the third embodiment.

### Sixth Embodiment

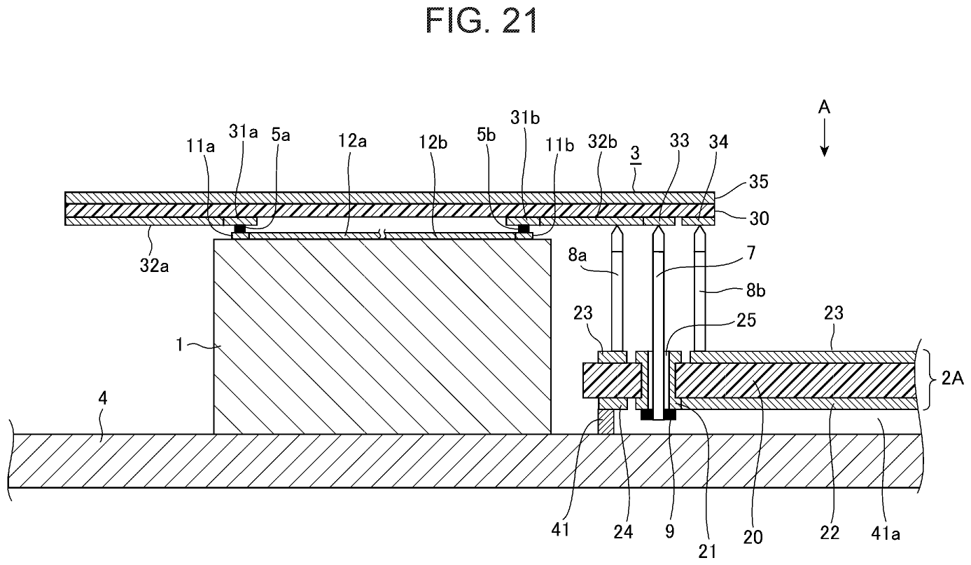

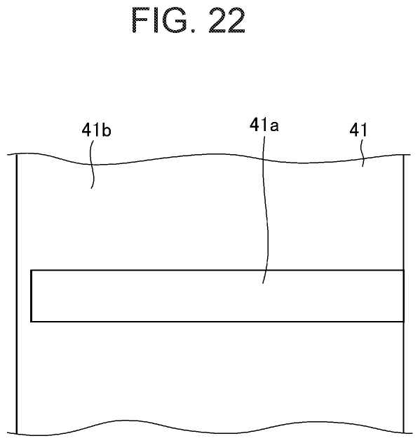

A semiconductor module according to a sixth embodiment will be described with reference to FIGS. 21 and 22.

The semiconductor module according to the sixth embodiment is different from the semiconductor module according to the third embodiment in the following points, and the other components are the same.

Note that in FIG. 21 the same symbols as those in FIG. 14 denote the same or corresponding parts.

That is, in contrast with the semiconductor module according to the third embodiment includes the recessed portion 4B1 on the front face of the heat dissipation plate 4B in order to physically separate the signal transmission portion 21 and the signal transmission line 22 of the transmission line body 2A from the front face of the heat dissipation plate 4B, in the semiconductor module according to the fifth embodiment, a spacer 41 surrounding a signal transmission portion 21 and a signal transmission line 22 of a transmission line body 2A and physically separating the signal transmission portion 21 and the signal transmission line 22 of the transmission line body 2A from a front face of the heat dissipation plate 4 is provided between a back face of the transmission line body 2A and the front face of the heat dissipation plate 4.

The spacer 41 includes a space portion 41a formed to surround the signal transmission portion 21 and the signal transmission line 22 formed on the back face of the transmission line body 2A and a frame body 41b formed at the surrounding position.

The spacer 41 is made of the same material as that of the heat dissipation plate 4. Note that the spacer 41 may be a conductor or an insulator whose face is plated.

The semiconductor module according to the sixth embodiment also achieves similar effects to those of the semiconductor module according to the third embodiment.

### Seventh Embodiment

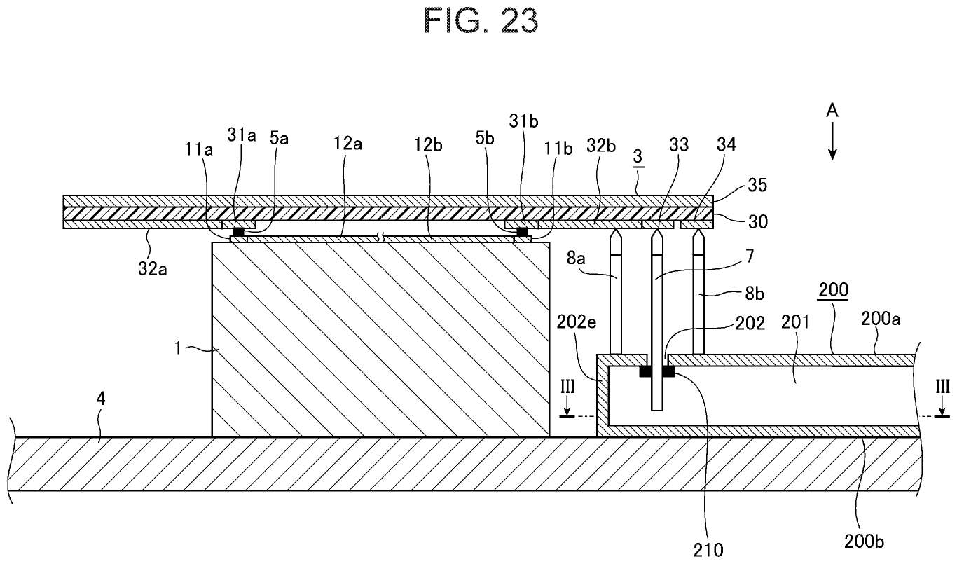

A semiconductor module according to a seventh embodiment will be described with reference to FIGS. 23 to 28.

The semiconductor module according to the seventh embodiment is different from the semiconductor module according to the first embodiment in the following points, and the other components are the same.

In FIGS. 23 to 26, the same symbols as those in the drawings used for description of the first embodiment denote the same or corresponding parts.

That is, the semiconductor module according to the seventh embodiment is different from the semiconductor module according to the first embodiment, in which a microstrip line is used as the transmission line body 2, in that a waveguide is used as a transmission line body 200, and the connection relationship among a signal connection terminal 7, a plurality of ground connection terminals 8a to 8f, and the waveguide is different due to this difference.

As illustrated in FIGS. 25 and 26, the transmission line body 200 is a waveguide made of a conductor, the transmission line body 200 having a rectangular longitudinal cross-section and including an upper wall 200a, a lower wall 200b, both side walls 200c and 200d, and a first end wall 200e, and a waveguide path 201 by the waveguide has a first end that is short-circuited and a second end that is opened.

Hereinafter, to facilitate understanding of the description, the transmission line body 200 will be described as a waveguide 200.

The waveguide path 201 by the waveguide 200 is a space surrounded by the upper wall 200a, the lower wall 200b, both the side walls 200c and 200d, and the first end wall 200e, and there is a feeding portion for a high-frequency signal of the waveguide path 201 on the first end wall 200e side.

This feeding portion is a signal transmission portion of the transmission line body 200.

In addition, the first end wall 200e of the waveguide 200 is short-circuited. That is, an inner face of the first end wall 200e of the waveguide 200 is a short-circuit plane.

The waveguide 200 has a terminal insertion hole 202, into which a rear end of a fixed portion 71 positioned at a second end of the signal connection terminal 7 is inserted, in the upper wall 200a at a position corresponding to the feeding portion for the high-frequency signal in the waveguide path 201.

As illustrated in FIG. 26, the shape of the waveguide path 201 by the waveguide 200 has a constant width and a constant height from the first end wall 200e to the open end.

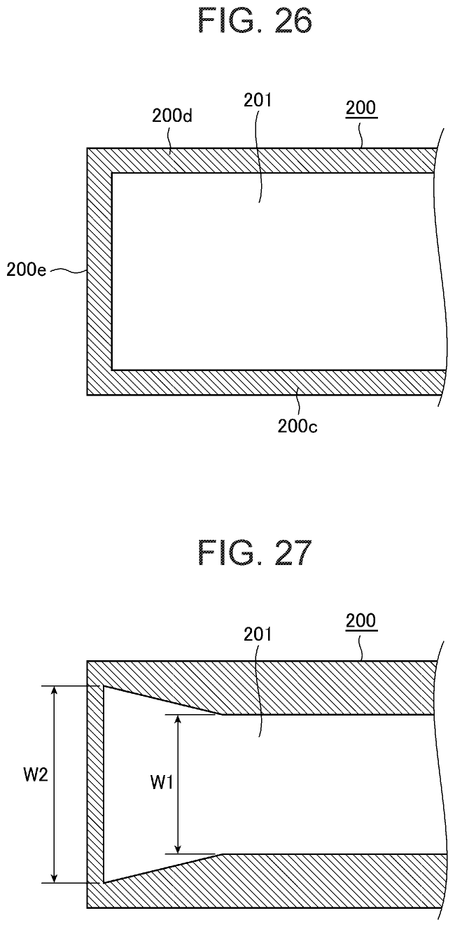

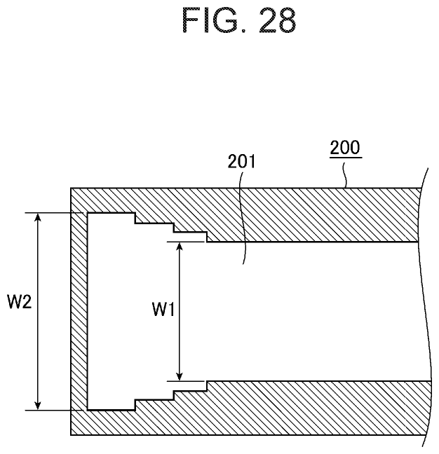

Note that, as illustrated in FIG. 27 which is a cross-sectional view taken along line of FIG. 23, the shape of the waveguide path 201 by the waveguide 200 may have, on the first end wall 200e side, a tapered portion tapered from a width W2 to a width W1 as it is separated from the first end wall 200e and have a constant width W1 continuously with the tapered portion up to the open end.

The width W1 and the width W2 are values selected in terms of design in order to achieve desired electrical characteristics.

In addition, the tapered portion from the first end wall 200e may be tapered to be wider as it is separated from the first end wall 200e contrary to the shape illustrated in FIG. 27.

Furthermore, as illustrated in FIG. 28, the shape of the waveguide path 201 by the waveguide 200 may have, on the first end wall 200e side, a stepped portion that becomes narrower stepwise as it is separated from the first end wall 200e from the width W2 to the width W1 and have the constant width W1 continuously with the stepped portion up to the open end.

The width W1, the width W2, and the stepped shape have values selected in terms of design in order to achieve desired electrical characteristics.

In addition, the stepped portion from the first end wall 200e may become wider as it is separated from the first end wall 200e contrary to the shape illustrated in FIG. 28.

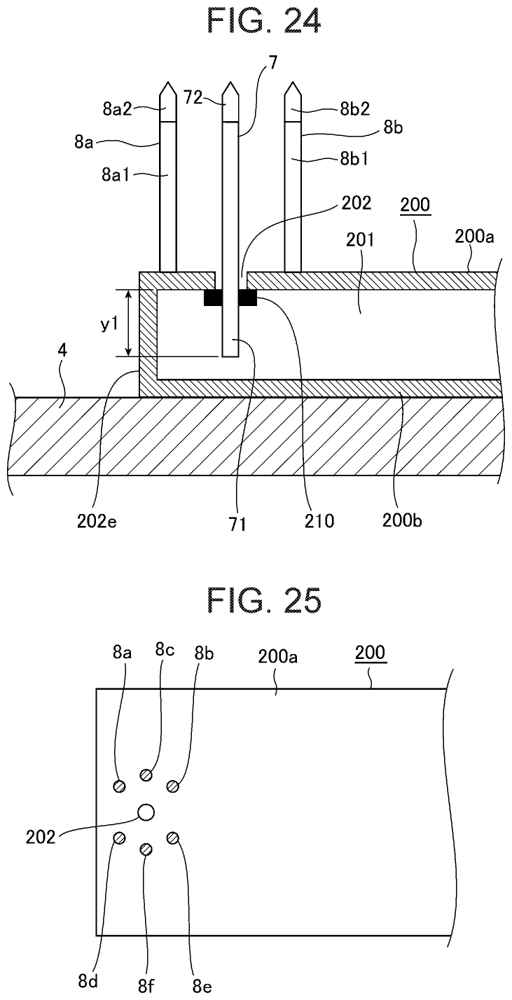

As illustrated in FIGS. 23 and 24, the rear end of the fixed portion 71 located at the second end of the signal connection terminal 7 passes through the terminal insertion hole 202, and the signal connection terminal 7 is fixed to the inner face of the upper wall 200a of the waveguide 200 by an insulating adhesive 210 at a rear end thereof.

Note that the signal connection terminal 7 may be fixed to the upper wall 200a of the waveguide 200 not on the inner face but on an outer face at the rear end by an insulating adhesive.

As illustrated in FIG. 24, the fixed portion 71 of the signal connection terminal 7 is inserted by a length y1 from a back face of the upper wall 200a of the waveguide 200. A portion of the fixed portion 71 inserted into the waveguide 200 functions as a feeding pin to feed, to a feeding portion, a high-frequency signal of the waveguide path 201 in the waveguide 200.

The length y1 of the fixed portion 71 that is inserted is adjusted to such a length that desired electrical characteristics can be obtained in connection between the waveguide 200 and a pseudo coaxial line constituted by the signal connection terminal 7 and a plurality of ground connection terminals 8a to 8f.

In the signal connection terminal 7, a movable portion 72 located at a first end protrudes from a front face of the upper wall 200a of the waveguide 200.

When the front face of the interposer substrate 3 on which the semiconductor element 1 is mounted is disposed to face the front face of the heat dissipation plate 4, the distal end of the movable portion 72 of the signal connection terminal 7 is pressed in contact with the transmission-line-body signal pad 33 formed on the front face of the interposer substrate 3, and the movable portion 72 of the signal connection terminal 7 moves toward the fixed portion 71.

As a result, the transmission-line-body signal pad 33 is brought into close contact with the distal end of the movable portion 72 of the signal connection terminal 7 in a state where pressure is applied to the distal end.

As illustrated in FIGS. 23 and 24, the plurality of ground connection terminals 8a to 8f is arranged to surround the signal connection terminal 7 and, together with the signal connection terminal 7, constitute the pseudo coaxial line.

As illustrated in FIGS. 23 to 25, the plurality of ground connection terminals 8a to 8f is arranged concentrically about the signal connection terminal 7 to surround the signal connection terminal 7, and rear ends of the fixed portions 8a1 to 8f1 located at second ends are electrically and mechanically connected to a front face of the upper wall 200a of the waveguide 200.

The periphery on the front face of the upper wall 200a of the waveguide 200 surrounding the signal connection terminal 7 serves as a ground portion.

In the plurality of ground connection terminals 8a to 8f, movable portions 8a2 to 8f2 located at first ends protrude from the front face of the upper wall 200a of the waveguide 200.

When the front face of the interposer substrate 3 on which the semiconductor element 1 is mounted is disposed to face the front face of the heat dissipation plate 4, distal ends of the movable portions 8a2 to 8f2 of the plurality of ground connection terminals 8a to 8f, respectively, are pressed in contact with the ground portion 34 formed on the front face of the interposer substrate 3, and the movable portions 8a2 to 8f2 of the plurality of ground connection terminals 8a to 8f move toward the fixed portions 8a1 to 8f1, respectively.

As a result, the ground portion 34 is brought into close contact with the distal ends of the movable portions 8a2 to 8f2 of the plurality of ground connection terminals 8a to 8f, respectively, in a state where pressure is applied to the distal ends.

Note that the number of the ground connection terminals 8a to 8f may be six or more or six or less, and a plurality of ground connection terminals may be arranged on linear lines on both sides of the signal connection terminal 7 similarly to the case illustrated in FIG. 11.

Furthermore, as illustrated in FIG. 12, in the signal connection terminal 7 and the ground connection terminals 8a to 8f, the fixed portions 71 and 8a1 to 8f1 may have a small diameter portion W2 having a smaller diameter than that of a spring mechanism housing portion F1 located on the movable portions 72 and 8a2 to 8f2 side.

In the semiconductor module according to the seventh embodiment, similarly to the semiconductor module according to the first embodiment, after a semiconductor element 1 is flip-chip mounted on a front face of an interposer substrate 3 using conductive adhesives 5a and 5b and conductive adhesives 6a to 6d, the interposer substrate 3 on which the semiconductor element 1 is mounted is pressed against a heat dissipation plate 4 in a direction of an arrow A illustrated in FIG. 23 in such a manner that the front face of the interposer substrate 3 faces the front face of the heat dissipation plate 4 and that a back face of the semiconductor element 1 is brought into close contact with the front face of the heat dissipation plate 4.

As a result, electric connection is made from an output signal line 12b and an output signal terminal 11b formed on the front face of the semiconductor element 1 with the feeding portion for a high-frequency signal of the waveguide path 201 located on the first end wall 200e side of the waveguide 200 by the signal connection terminal 7 via an output-side semiconductor-element signal pad 31b and an output-side signal line 32b formed on the front face of the interposer substrate 3 and a transmission-line-body signal pad 33, and the high-frequency signal is fed into the waveguide path 201 by the waveguide 200 from a portion functioning as a feeding pin in the fixed portion 71 of the signal connection terminal 7.

As described above, in the semiconductor module according to the seventh embodiment, the semiconductor element 1 is flip-chip mounted on the interposer substrate 3, and connection between an input signal terminal 11a and the output signal terminal 11b of the semiconductor element 1 and an input-side semiconductor-element signal pad 31a and an output-side semiconductor-element signal pad 31b of the interposer substrate 3, respectively, and connection between ground terminals 13a to 13d of the semiconductor element 1 and the ground portion 34 of the interposer substrate 3 are made by the conductive adhesives 5a, 5b, and 6a to 6d, and the conductive adhesives 5a, 5b, and 6a to 6d are small, and the mounting tolerance is also small. Therefore, the influence of parasitic inductance and deterioration of electrical characteristics can be reduced.

In addition, in the semiconductor module according to the seventh embodiment, the transmission-line-body signal pad 33 of the interposer substrate 3 and the feeding portion for a high-frequency signal of the waveguide path 201 located on the first end wall 200e side of the waveguide 200 are connected by the signal connection terminal 7 having the movable portion that expands and contracts with respect to the fixed portion, and the ground portion 34 of the interposer substrate 3 and a periphery serving as a ground portion on the front face of the upper wall 200a of the waveguide 200 surrounding the signal connection terminal 7 are connected by the plurality of ground connection terminals 8a to 8f to surround the signal connection terminal 7, the plurality of ground connection terminals 8a to 8f each having a movable portion that expands and contracts with respect to a fixed portion, and the pseudo coaxial line constituted by the signal connection terminal 7 and the plurality of ground connection terminals 8a to 8f includes connection terminals having movable portions. Therefore, it is possible to surely assemble the semiconductor element 1 and the transmission line body 2 even in a case where there is a tolerance, namely, a level difference, in the thickness direction thereof, thereby ensuring electrical connection and enabling reliable transmission of the high-frequency signal.

Furthermore, in the semiconductor module according to the seventh embodiment, even in a case where there is a tolerance, namely, a level difference in the thickness direction between the semiconductor element 1 and the waveguide 200, since the signal connection terminal 7 and the plurality of ground connection terminals 8a to 8f absorb the level difference, the interposer substrate 3 on which the semiconductor element 1 is mounted can be pressed against the heat dissipation plate 4, the back face of the semiconductor element 1 and the back face of the waveguide 200 can be brought into close contact with the front face of the heat dissipation plate 4, the interposer substrate 3 on which the semiconductor element 1 is mounted and the waveguide 200 can be stably mounted on the heat dissipation plate 4, thermal resistance between the back face of the semiconductor element 1 and the front face of the heat dissipation plate 4 can be reduced, and heat generated by the semiconductor element 1 can be dissipated by the heat dissipation plate 4 efficiently.

In the semiconductor module according to the seventh embodiment, since the transmission line body 200 is the waveguide 200, withstand power as a transmission line body for high-frequency signal is improved, thereby contributing to an increase in power as a high frequency module.

The semiconductor module according to the seventh embodiment has a configuration in which the transmission-line-body signal pad 33 of the interposer substrate 3 and the feeding portion for the high-frequency signal of the waveguide path 201 are connected in the vertical direction by the signal connection terminal 7, and the ground portion 34 of the interposer substrate 3 and the periphery serving as the ground portion on the front face of the upper wall 200a of the waveguide 200 surrounding the signal connection terminal 7 are connected in the vertical direction by the plurality of ground connection terminals 8a to 8f Therefore, the semiconductor module can be downsized as compared with a module in which the interposer substrate 3 and the waveguide 200 are arranged in the horizontal direction.

### Eighth Embodiment

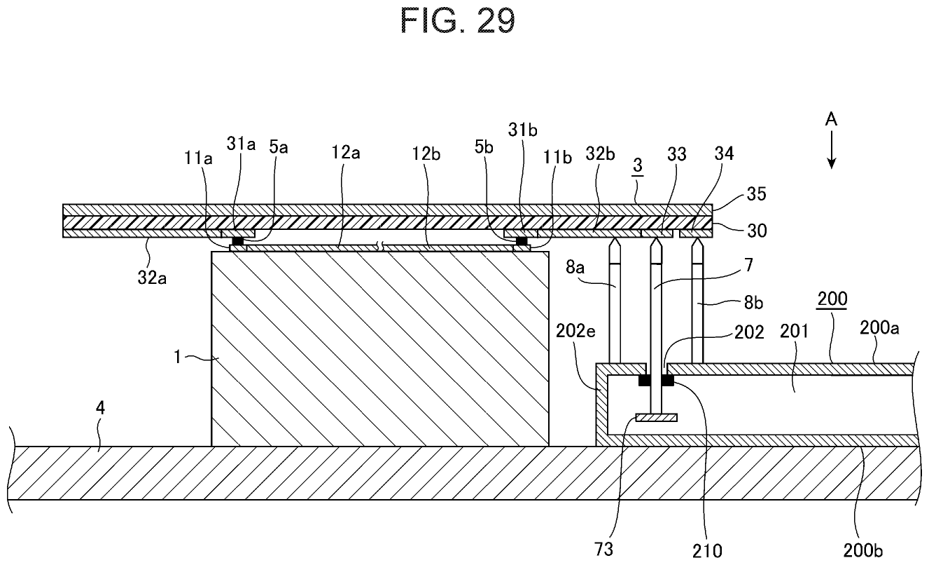

A semiconductor module according to an eighth embodiment will be described with reference to FIGS. 29 to 31.

The semiconductor module according to the eighth embodiment is different from the semiconductor module according to the seventh embodiment in the following points, and the other components are the same.

Note that in FIG. 29 the same symbols as those in FIG. 23 denote the same or corresponding parts.

That is, the semiconductor module according to the eighth embodiment is different from the semiconductor module according to the seventh embodiment in that, as illustrated in FIG. 29, a conductor plate 73 is attached to a portion of a fixed portion 71 located at a second end of a signal connection terminal 7, the portion inserted in a waveguide path.

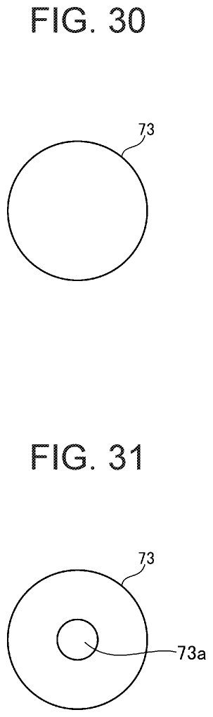

As illustrated in FIG. 30, the conductor plate 73 is a circular metal plate, and the conductor plate 73 is connected to the fixed portion 71 of the signal connection terminal 7 by a conductive adhesive such as solder with a rear end of the fixed portion 71 of the signal connection terminal 7 brought into contact with the center of a front face of the conductor plate 73.

The conductor plate 73 is provided in order to adjust electrical characteristics between the signal connection terminal 7 and a waveguide path 201.

Note that, as illustrated in FIG. 31, the conductor plate 73 may have a through-hole 73a, in which the rear end of the fixed portion 71 of the signal connection terminal 7 is inserted, at the center of the circular metal plate, or the rear end of the fixed portion 71 of the signal connection terminal 7 may be inserted in the through-hole 73a, and the conductor plate 73 may be connected to the fixed portion 71 of the signal connection terminal 7 by a conductive adhesive such as solder.

In the semiconductor module according to the eighth embodiment, as described in the semiconductor module according to the seventh embodiment, the shape of the waveguide path 201 may be any of a shape having a constant width from a first end to an open end, a shape having a tapered portion on the first end side, and a shape having a stepped portion on the first end side.

The semiconductor module according to the eighth embodiment also achieves similar effects to those of the semiconductor module according to the seventh embodiment.

### Ninth Embodiment

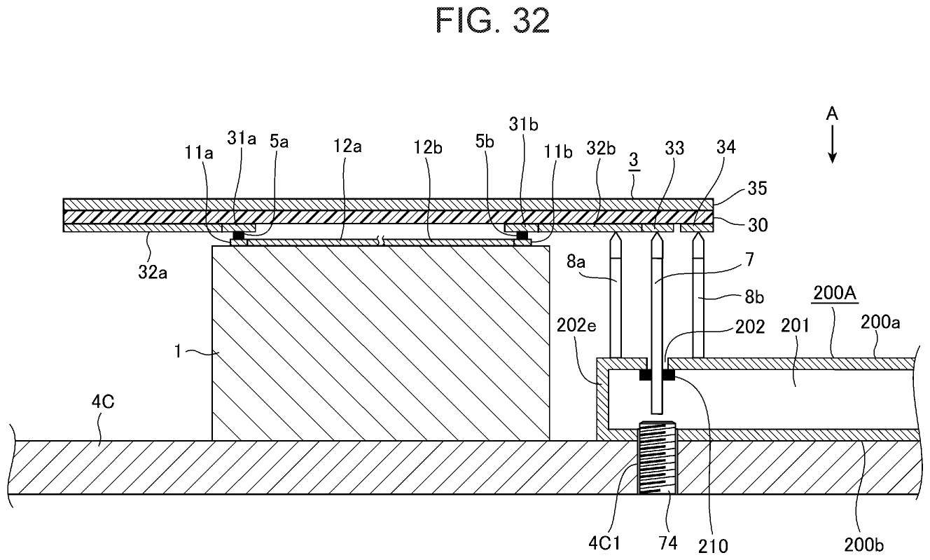

A semiconductor module according to a ninth embodiment will be described with reference to FIGS. 32 to 34.

The semiconductor module according to the ninth embodiment is different from the semiconductor module according to the seventh embodiment in the following points, and the other components are the same.

Note that in FIG. 32 the same symbols as those in FIG. 23 denote the same or corresponding parts.

That is, the semiconductor module according to the ninth embodiment is different from the semiconductor module according to the seventh embodiment in that, as illustrated in FIG. 32, a metal column 74 is included, the metal column 74 having a distal end positioned inside a waveguide path 201 and separated from and facing a fixed portion 71 of a signal connection terminal 7, the metal column 74 mounted in a heat dissipation plate 4C.

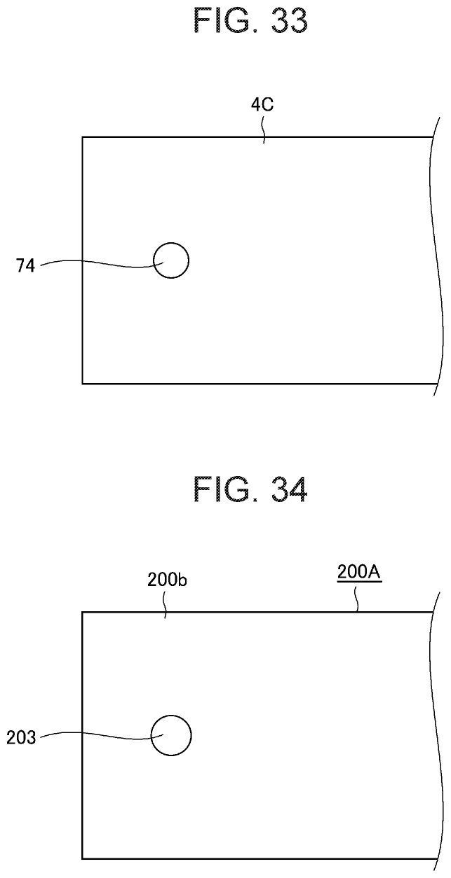

As illustrated in FIGS. 32 and 33, the heat dissipation plate 4C has a mounting portion 4C1, which is a screw hole, formed at a position facing a rear end of the fixed portion 71 located at the second end of the signal connection terminal 7.

As illustrated in FIGS. 32 and 34, a through-hole 203 is formed in a lower wall 200b of a waveguide 200 at a position facing the rear end of the fixed portion 71 located at the second end of signal connection terminal 7.

The central axis of the screw hole which is the mounting portion 4C1 of the heat dissipation plate 4C and the central axis of the through-hole 203 of the lower wall 200b of the waveguide 200 are coaxial.

A screw serving as the metal column 74 is screwed and inserted into the screw hole serving as the mounting portion 4C1 from a back face of the heat dissipation plate 4C, passes through the through-hole 203 of the lower wall 200b of the waveguide 200, and a distal end is located inside the waveguide path 201.

A distal end face of the distal end of the metal column 74 and a rear end face of the fixed portion 71 of the signal connection terminal 7 face each other but are not in contact with each other.

The metal column 74 is provided in order to adjust electrical characteristics between the signal connection terminal 7 and the waveguide path 201.

The metal column 74 is not limited to a screw and may be any rod-shaped metal. In this case, the mounting portion 4C1 of the heat dissipation plate 4C is a through-hole into which a rod-shaped metal is inserted and fixed by a conductive adhesive.

Note that, also in the semiconductor module according to the ninth embodiment, as described in the semiconductor module according to the seventh embodiment, the shape of the waveguide path 201 may be any of a shape having a constant width from a first end to an open end, a shape having a tapered portion on the first end side, and a shape having a stepped portion on the first end side.

Moreover, also in the semiconductor module according to the ninth embodiment, as described in the semiconductor module according to the eighth embodiment, a conductor plate 73 may be attached to the fixed portion 71 of the signal connection terminal 7.

The semiconductor module according to the ninth embodiment also achieves similar effects to those of the semiconductor module according to the seventh embodiment.

### Tenth Embodiment

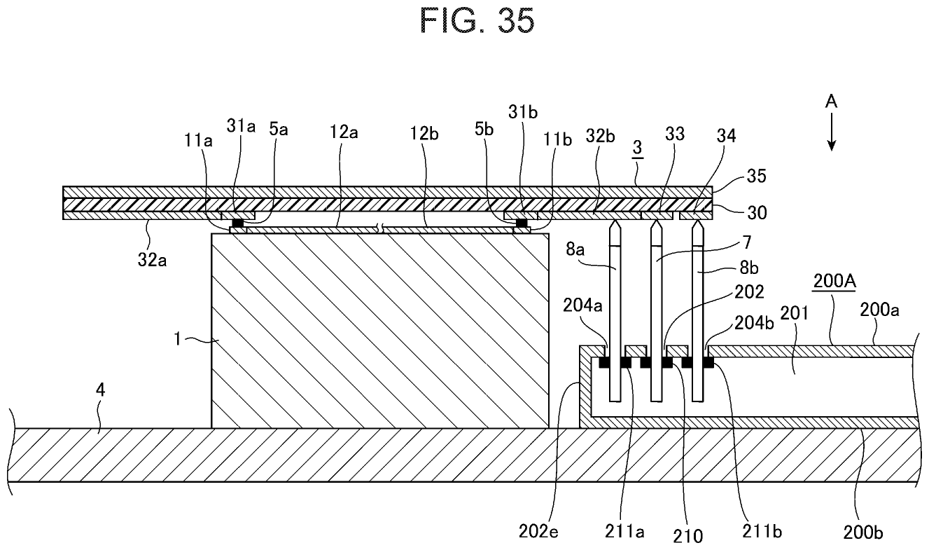

A semiconductor module according to a tenth embodiment will be described with reference to FIGS. 35 to 37.

The semiconductor module according to the tenth embodiment is different from the semiconductor module according to the seventh embodiment in the following points, and the other components are the same.

Note that in FIGS. 35 to 37 the same symbols as those in FIGS. 23 to 25 denote the same or corresponding parts.

In addition, in FIGS. 35 to 37, ground connection terminals 8a and 8b are also illustrated in a cross section to facilitate understanding.

That is, as illustrated in FIG. 37, a waveguide 200A in the semiconductor module according to the tenth embodiment is different from the waveguide 200 of the semiconductor module according to the seventh embodiment in that a plurality of terminal insertion holes 204a to 204f is included in an upper wall 200a of the waveguide 200A in correspondence with the plurality of ground connection terminals 8a to 8f, and the connection relationship between the plurality of ground connection terminals 8a to 8f and the waveguide 200A is different due to this difference.

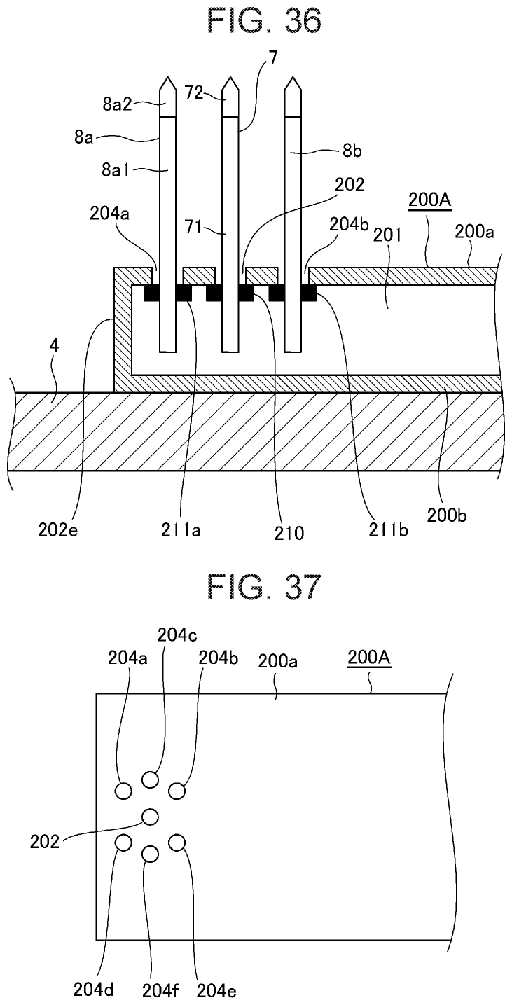

As illustrated in FIGS. 35 and 36, the plurality of ground connection terminals 8a to 8f is inserted through the respective terminal insertion holes 204a to 204f at rear ends of fixed portions 8a1 to 8f1 positioned at second ends thereof and are electrically and mechanically connected to an inner face of the upper wall 200a of the waveguide 200A by conductive adhesives 211a to 211f such as solder at the rear ends.

Note that the plurality of ground connection terminals 8a to 8f may be fixed to the upper wall 200a of the waveguide 200A not on the inner face but on an outer face at the rear ends by a conductive adhesive.

Note that, also in the semiconductor module according to the tenth embodiment, as described in the semiconductor module according to the seventh embodiment, the shape of the waveguide path 201 may be any of a shape having a constant width from a first end to an open end, a shape having a tapered portion on the first end side, and a shape having a stepped portion on the first end side.

Moreover, also in the semiconductor module according to the tenth embodiment, as described in the semiconductor module according to the eighth embodiment, a conductor plate 73 may be attached to the fixed portion 71 of the signal connection terminal 7.

Furthermore, also in the semiconductor module according to the tenth embodiment, as described in the semiconductor module according to the ninth embodiment, a metal column 74 mounted in a heat dissipation plate 4 may be included, the metal column 74 having a distal end positioned inside the waveguide path 201 and facing the fixed portion 71 of the signal connection terminal 7.

The semiconductor module according to the tenth embodiment also achieves similar effects to those of the semiconductor module according to the seventh embodiment.

### Eleventh Embodiment

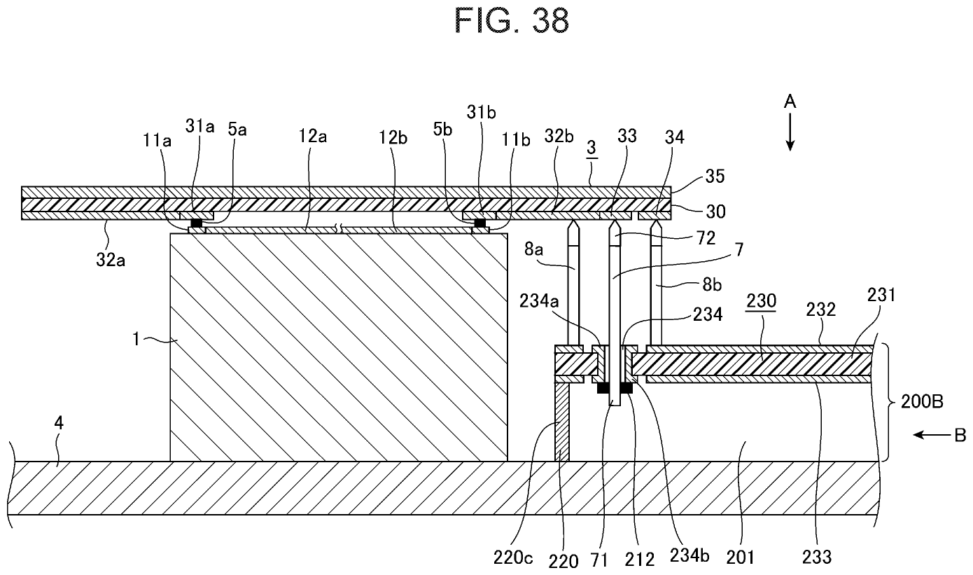

A semiconductor module according to an eleventh embodiment will be described with reference to FIGS. 38 to 42.

The semiconductor module according to the eleventh embodiment is different from the semiconductor module according to the seventh embodiment in the following points, and the other components are the same.

Note that in FIG. 38 the same symbols as those in FIG. 23 denote the same or corresponding parts.

That is, a transmission line body 200B in the semiconductor module according to the eleventh embodiment is different from the transmission line body 200 in the semiconductor module according to the seventh embodiment in that the transmission line body 200B is a waveguide including a conductor side wall 220 and a conductor upper wall 230 made of a conductor, and the connection relationship between a set of a signal connection terminal 7 and a plurality of ground connection terminals 8a to 8f and the waveguide is different due to this difference.

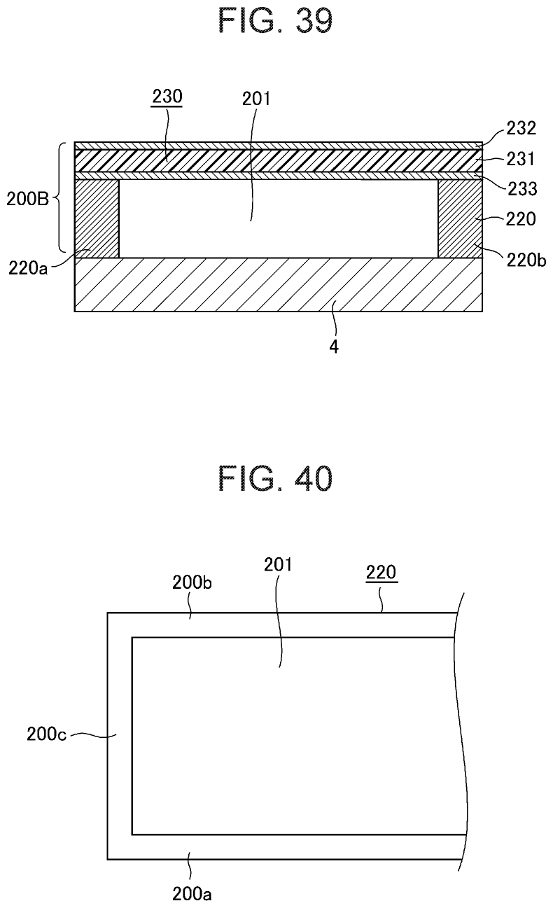

As illustrated in FIG. 40, the conductor side wall 220 includes both side walls 220a and 220b and a first end wall 220c, and as illustrated in FIGS. 38 and 39, bottom faces of both the side walls 220a and 220b and the first end wall 220c are in close contact with a front face of a heat dissipation plate 4.

The conductor upper wall 230 includes an upper wall substrate 231 made of a dielectric and ground conductors 232 and 233 on a front face and a back face of the upper wall substrate 231, respectively.

In the conductor upper wall 230, the ground conductors 232 and 233 are electrically connected by a plurality of vias penetrating from the front face to the back face of the upper wall substrate 231.

Each of front faces of both the side walls 220a and 220b and the first end wall 220c of the conductor side wall 220 and the ground conductor 233 of the conductor upper wall 230 are fixed by, for example, a conductive adhesive such as solder.

A space surrounded by inner faces of both the side walls 220a and 220b and the first end wall 220c of the conductor side wall 220 and faces of the ground conductor 233 of the conductor upper wall 230 and the heat dissipation plate 4 forms a waveguide path 201 in which a first end is short-circuited and a second end is opened.

On the first end wall 220c side of the waveguide path 201, there is a feeding portion for a high-frequency signal of the waveguide path 201.

This feeding portion is a signal transmission portion of the transmission line body 200B.

The conductor upper wall 230 has a terminal insertion hole 234 by a through-via at a position corresponding to the feeding portion for the high-frequency signal of the waveguide path 201.

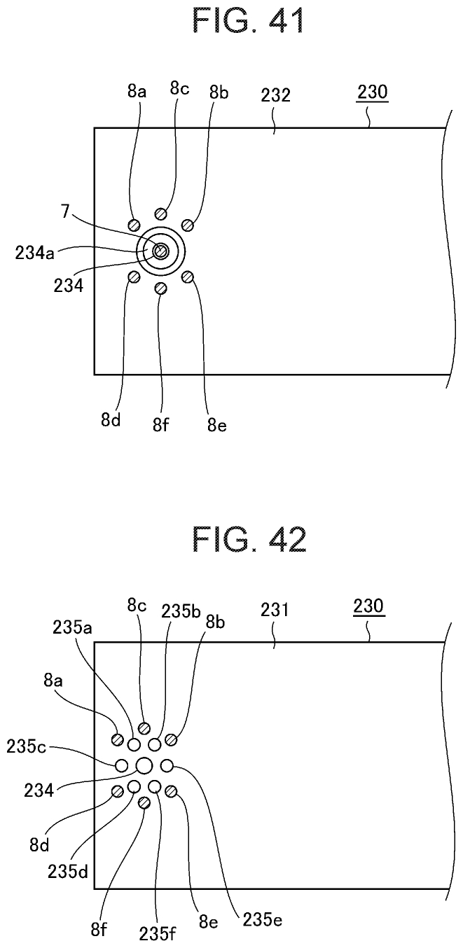

As illustrated in FIGS. 38 and 41, the through-via which is the terminal insertion hole 234 has a land 234a electrically and physically separated from the ground conductor 232 on the front face of the conductor upper wall 230 and a land 234b electrically and physically separated from the ground conductor 233 on the back face of the conductor upper wall 230.

As illustrated in FIG. 38, the signal connection terminal 7 is fixed to the conductor upper wall 230 with a rear end of a fixed portion 71 located at a second end inserted in the terminal insertion hole 234 and with the rear end bonded to the land 234b with a conductive adhesive 212.

In fixing the signal connection terminal 7 to the conductor upper wall 230, the rear end may be bonded to the land 234a with a conductive adhesive.

A portion of the fixed portion 71 of the signal connection terminal 7 inserted in the waveguide path 201 functions as a feeding pin to feed, to the feeding portion, the high-frequency signal of the waveguide path 201 in the transmission line body 200B.

As illustrated in FIGS. 38 and 41, the plurality of ground connection terminals 8a to 8f is arranged concentrically about the signal connection terminal 7 to surround the signal connection terminal 7, and rear ends of fixed portions 8a1 to 8f1 located at second ends are electrically and mechanically connected to a front face of the ground conductor 232 of the conductor upper wall 230.

The periphery on the front face of the ground conductor 232 of the conductor upper wall 230 surrounding the signal connection terminal 7 serves as a ground portion.

Note that, in the conductor upper wall 230 as illustrated in FIG. 42, vias 235a to 235f may be formed, the vias 235a to 235f arranged between the terminal insertion hole 234 and the plurality of ground connection terminals 8a to 8f to surround the terminal insertion hole 234 concentrically with the terminal insertion hole 234 in the center and electrically connecting the ground conductors 232 and 233, and a pseudo coaxial line may be included in which the through-via which is the terminal insertion hole 234 serves as an inner conductor and the vias 235a to 235f serve as outer conductors.

The vias 235a to 235f may be through-vias or filling lid-plated vias depending on the specifications.

In addition, the arrangement of and the number of the vias 235a to 235f is not limited as long as a desired characteristic impedance of the pseudo coaxial line can be achieved.

Furthermore, as the vias 235a to 235f, a plurality of vias may be arranged at any and each position on the conductor upper wall 230 in order to prevent electrical interference with the waveguide path 201 and a transmission line formed in an interposer substrate 3.

Note that, also in the semiconductor module according to the eleventh embodiment, as described in the semiconductor module according to the seventh embodiment, the shape of the waveguide path 201 may be any of a shape having a constant width from a first end to an open end, a shape having a tapered portion on the first end side, and a shape having a stepped portion on the first end side.

Moreover, also in the semiconductor module according to the eleventh embodiment, as described in the semiconductor module according to the eighth embodiment, a conductor plate 73 may be attached to the fixed portion 71 of the signal connection terminal 7.

Furthermore, also in the semiconductor module according to the eleventh embodiment, as described in the semiconductor module according to the ninth embodiment, a metal column 74 mounted in a heat dissipation plate 4C may be included, the metal column 74 having a distal end positioned inside the waveguide path 201 and facing the fixed portion 71 of the signal connection terminal 7.

The semiconductor module according to the eleventh embodiment also achieves similar effects to those of the semiconductor module according to the seventh embodiment.

Moreover, since the semiconductor module according to the eleventh embodiment uses the waveguide including the conductor side wall and the conductor upper wall made of a conductor, a chip component such as a chip capacitor can be mounted on a portion not used as the waveguide path in the conductor upper wall, and thus a signal line such as another microstrip line can be formed, whereby a highly dense configuration can be implemented.

### Twelfth Embodiment

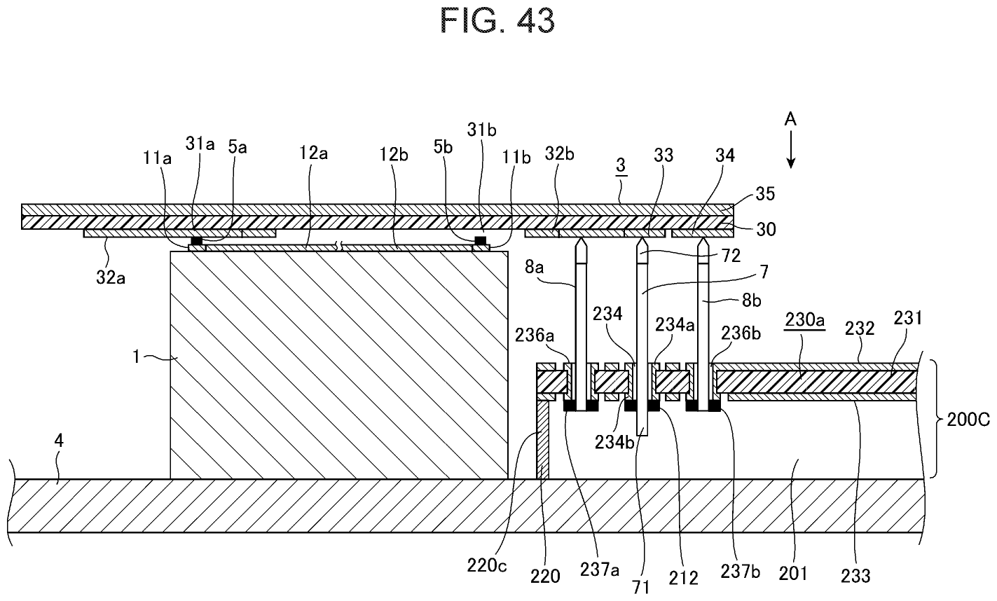

A semiconductor module according to a twelfth embodiment will be described with reference to FIGS. 43 and 45.

The semiconductor module according to the twelfth embodiment is different from the semiconductor module according to the eleventh embodiment in the following points, and the other components are the same.

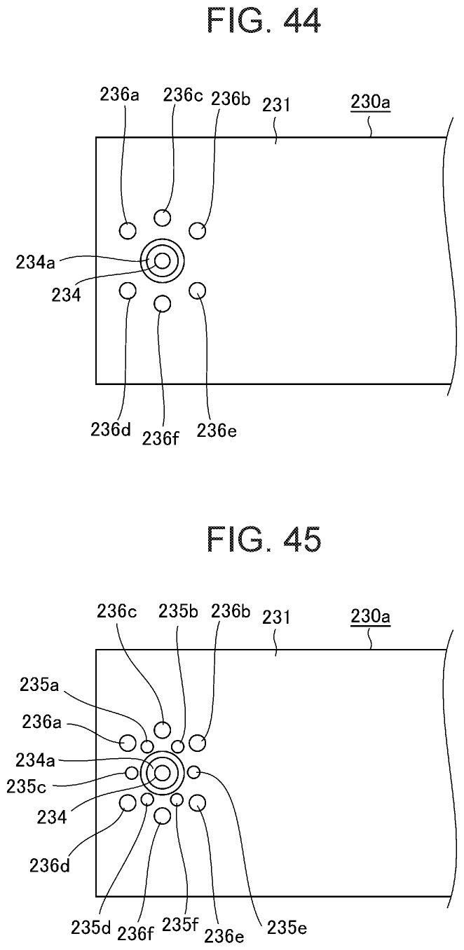

Note that in FIGS. 43 and 44 the same symbols as those in FIGS. 38 and 41 denote the same or corresponding parts.

In addition, in FIG. 43, ground connection terminals 8a and 8b are also illustrated in a cross section to facilitate understanding.

That is, the transmission line body 200C in the semiconductor module according to the twelfth embodiment is different from the transmission line body 200B in the semiconductor module according to the eleventh embodiment in that, as illustrated in FIG. 44, a plurality of through-vias 236a to 236f is included in a conductor upper wall 230a of the transmission line body 200C in correspondence with a plurality of ground connection terminals 8a to 8f, and the connection relationship between the plurality of ground connection terminals 8a to 8f and ground conductors 232 and 233 of the conductor upper wall 230a is different due to this difference.

As illustrated in FIG. 44, the plurality of through-vias 236a to 236f is arranged to surround the signal connection terminal 7, and each of the through-vias 236a to 236f is a through-via electrically connecting the ground conductor 232 and the ground conductor 233 of the conductor upper wall 230a.

As illustrated in FIG. 43, the plurality of ground connection terminals 8a to 8f is inserted through the respective through-vias 236a to 236f at rear ends of fixed portions 8a1 to 8f1 positioned at second ends thereof and are electrically and mechanically connected to a front face of the ground conductor 233 of the conductor upper wall 230a by conductive adhesives 237a to 237f such as solder at the rear ends.

Note that the plurality of ground connection terminals 8a to 8f may be fixed to a front face of the ground conductor 232 of the conductor upper wall 230a with a conductive adhesive.

In addition, the length of the plurality of ground connection terminals 8a to 8f extending inside the waveguide path 201 may be of any value as long as electrical characteristics are not affected.

Note that, in the conductor upper wall 230a as illustrated in FIG. 45, vias 235a to 235f may be formed, the vias 235a to 235f arranged between the terminal insertion hole 234 and the plurality of through-vias 236a to 236f to surround the terminal insertion hole 234 concentrically with the terminal insertion hole 234 in the center and electrically connecting the ground conductors 232 and 233, and a pseudo coaxial line may be included in which the through-via which is the terminal insertion hole 234 serves as an inner conductor and the vias 235a to 235f serve as outer conductors.

The semiconductor module according to the twelfth embodiment also achieves similar effects to those of the semiconductor module according to the tenth embodiment.

Moreover, since the semiconductor module according to the twelfth embodiment uses the waveguide including the conductor side wall and the conductor upper wall made of a conductor, a chip component such as a chip capacitor can be mounted on a portion not used as the waveguide path in the conductor upper wall, and thus a signal line such as another microstrip line can be formed, whereby a highly dense configuration can be implemented.

### Thirteenth Embodiment

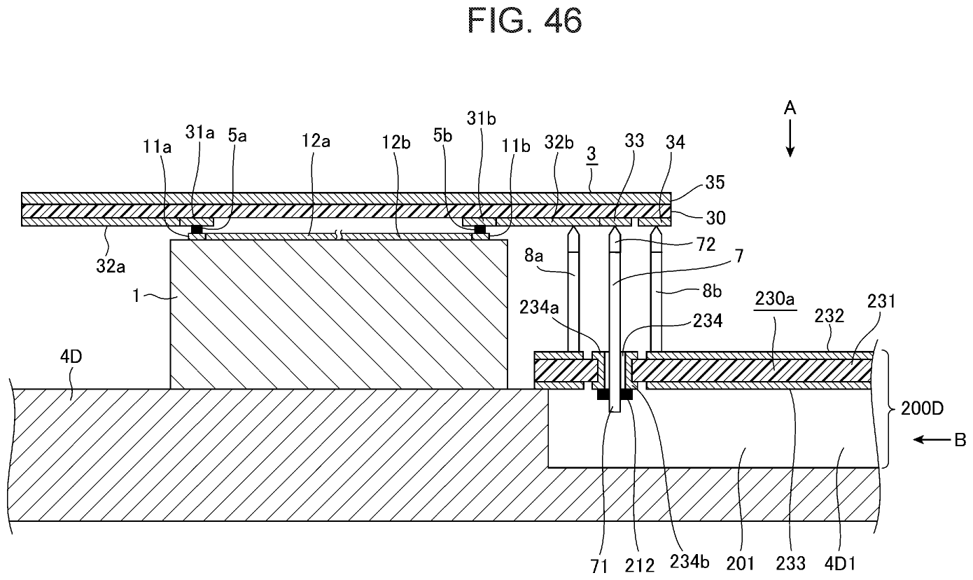

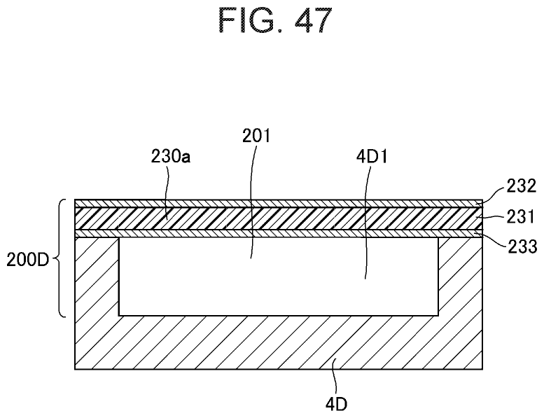

A semiconductor module according to a thirteenth embodiment will be described with reference to FIGS. 46 and 47.

The semiconductor module according to the thirteenth embodiment is different from the semiconductor module according to the seventh embodiment in the following points, and the other components are the same.

Note that in FIGS. 46 and 47 the same symbols as those in FIG. 23 denote the same or corresponding parts.

That is, a transmission line body 200D in the semiconductor module according to the thirteenth embodiment is different from the transmission line body 200 in the semiconductor module according to the seventh embodiment in that the transmission line body 200D is a waveguide including a waveguide groove 4D1 included in a waveguide path 201 formed in a heat dissipation plate 4D that is a metal plate and a conductor upper wall 230a made of a conductor, and the connection relationship between a set, of a signal connection terminal 7 and a plurality of ground connection terminals 8a to 8f, and the waveguide is different due to this difference.

The waveguide groove 4D1 is formed on a front face of the heat dissipation plate 4D at a position where a high-frequency signal from the signal connection terminal 7 is transmitted.

As illustrated in FIG. 47, the waveguide groove 4D1 has a rectangular longitudinal cross section and has a first end opened.

The conductor upper wall 230a includes an upper wall substrate 231 made of a dielectric and ground conductors 232 and 233 on a front face and a back face of the upper wall substrate 231, respectively.

In the conductor upper wall 230a, the ground conductors 232 and 233 are electrically connected by a plurality of vias penetrating from the front face to the back face of the upper wall substrate 231.

The conductor upper wall 230a covers the waveguide groove 4D1 of the heat dissipation plate 4D, the ground conductor 233 of the conductor upper wall 230a is in close contact with the front face of the heat dissipation plate 4D, and the ground conductor 233 of the conductor upper wall 230a and the front face of the heat dissipation plate 4D are connected by a conductive adhesive such as solder.

A space surrounded by the ground conductor 233 of the conductor upper wall 230a and the waveguide groove 4D1 of the heat dissipation plate 4D forms the waveguide path 201 in which a first end is short-circuited and a second end is opened.

On the first end side of the waveguide path 201, there is a feeding portion for a high-frequency signal of the waveguide path 201.

This feeding portion is a signal transmission portion of the transmission line body 200D.

The conductor upper wall 230a has a terminal insertion hole 234 by a through-via at a position corresponding to the feeding portion for the high-frequency signal of the waveguide path 201.

As illustrated in FIG. 46, the signal connection terminal 7 is fixed to the conductor upper wall 230a with a rear end of a fixed portion 71 located at a second end inserted in the terminal insertion hole 234 and with the rear end bonded to a land of the through-via, which is the terminal insertion hole 234, with a conductive adhesive 212.

A portion of the fixed portion 71 of the signal connection terminal 7 inserted in the waveguide path 201 functions as a feeding pin to feed, to the feeding portion, the high-frequency signal of the waveguide path 201 in the transmission line body 200D.

As illustrated in FIG. 46, the plurality of ground connection terminals 8a to 8f is arranged concentrically about the signal connection terminal 7 to surround the signal connection terminal 7, and rear ends of fixed portions 8a1 to 8f1 located at second ends are electrically and mechanically connected to a front face of the ground conductor 232 of the conductor upper wall 230a.

The periphery on the front face of the ground conductor 232 of the conductor upper wall 230a surrounding the signal connection terminal 7 serves as a ground portion.

Note that, also in the semiconductor module according to the thirteenth embodiment, as described in the semiconductor module according to the seventh embodiment, the shape of the waveguide path 201 may be any of a shape having a constant width from a first end to an open end, a shape having a tapered portion on the first end side, and a shape having a stepped portion on the first end side.

Moreover, also in the semiconductor module according to the thirteenth embodiment, as described in the semiconductor module according to the eighth embodiment, a conductor plate 73 may be attached to the fixed portion 71 of the signal connection terminal 7.

Furthermore, also in the semiconductor module according to the thirteenth embodiment, similarly to the metal column 74 described in the semiconductor module according to the ninth embodiment, a metal column 74 mounted in the heat dissipation plate 4D in the waveguide groove 4D1 may be included, the metal column 74 having a distal end positioned inside the waveguide path 201 and facing the fixed portion 71 of the signal connection terminal 7.

Furthermore, also in the semiconductor module according to the thirteenth embodiment, as described in the semiconductor module according to the twelfth embodiment, a plurality of through-vias 236a to 236f may be formed in the conductor upper wall 230a of the transmission line body 200D in correspondence with the plurality of ground connection terminals 8a to 8f, and the plurality of ground connection terminals 8a to 8f may be inserted through the respective through-vias 236a to 236f at rear ends of fixed portions 8a1 to 8f1 positioned at second ends thereof and be electrically and mechanically connected to a front face of the ground conductor 233 of the conductor upper wall 230a by conductive adhesives 237a to 237f such as solder at the rear ends.

The semiconductor module according to the thirteenth embodiment also achieves similar effects to those of the semiconductor module according to the seventh embodiment.

Moreover, in the semiconductor module according to the thirteenth embodiment, the waveguide groove serving as waveguide side wall faces and a waveguide bottom face included in the waveguide is formed in the heat dissipation plate which is a metal plate, and the waveguide is constituted by the waveguide side wall faces and the waveguide bottom face in the waveguide groove and the conductor upper wall made of a conductor, and thus it is possible to manufacture the semiconductor module at low cost without using a separate member.

Moreover, a chip component such as a chip capacitor can be mounted on a portion not used as the waveguide path in the conductor upper wall, and thus a signal line such as another microstrip line can be formed, whereby a highly dense configuration can be implemented.

### Fourteenth Embodiment

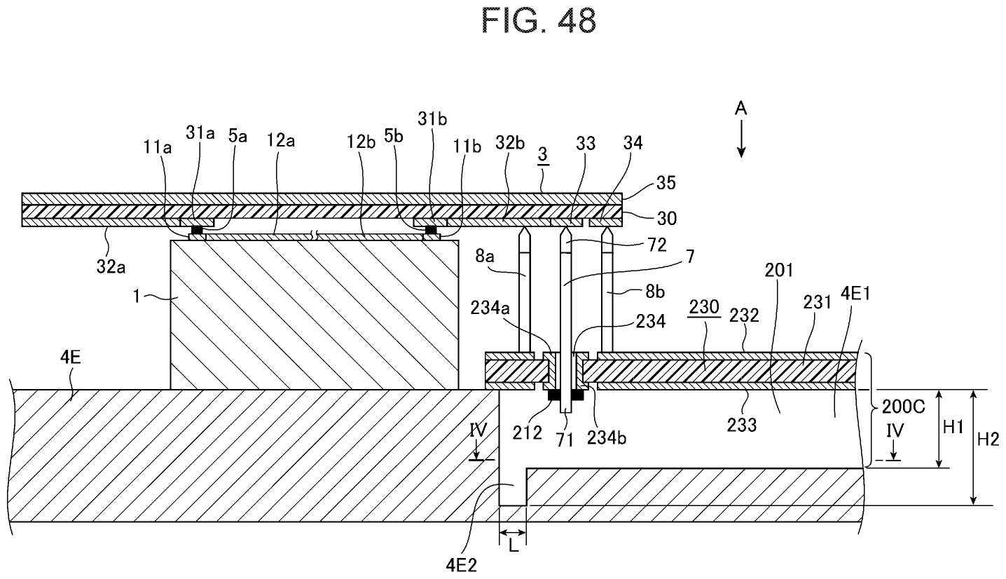

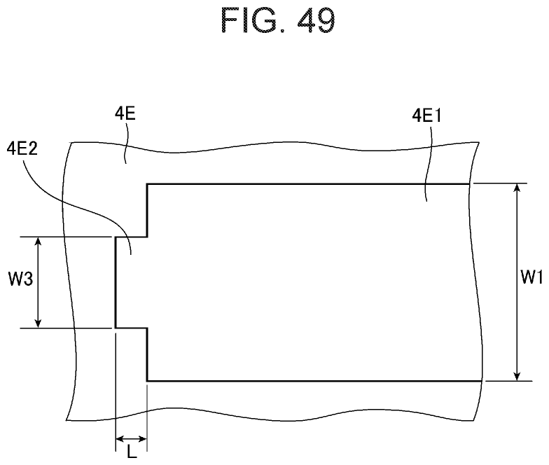

A semiconductor module according to a fourteenth embodiment will be described with reference to FIGS. 48 and 49.

The semiconductor module according to the fourteenth embodiment is different from the semiconductor module according to the thirteenth embodiment in the following points, and the other components are the same.

Note that in FIG. 48 the same symbols as those in FIG. 46 denote the same or corresponding parts.

That is, as compared to the waveguide groove 4D1 in the heat dissipation plate 4D of the semiconductor module according to the thirteenth embodiment, the semiconductor module according to the fourteenth embodiment is different in that a waveguide groove having a main groove 4E1 and a sub-groove 4E2 is formed in a heat dissipation plate 4E.

As for the shape of the main groove 4E1 in the waveguide groove, as illustrated in FIGS. 48 and 49, the longitudinal cross section is rectangular with a width of W1 and a depth of H1.

The longitudinal cross section is rectangular and a second end is open.

As illustrated in FIGS. 48 and 49, the sub-groove 4E2 in the waveguide groove communicates with the main groove 4E1 on a first end side, and as for the shape of the sub-groove 4E2, a longitudinal cross section is rectangular with a width of W3 narrower than the width W1 and a depth of H2 deeper than the depth H1.

Note that the relationship between the depth H1 of the main groove 4E1 and the depth H2 of the sub-groove 4E2 is not limited to one in which the depth H2 is deeper than the depth H1, and the depth H2 may be the same as the depth H1 or shallower than the depth H1. Likewise, the relationship between the width W1 of the main groove 4E1 and the width W3 of the sub-groove 4E2 is not limited to one in which the width W3 is narrower than the width W1, and the width W3 may be the same as the width W1 or wider than the width W1. In short, a length L in the transmission direction of a high-frequency signal in the sub-groove 4E2, the relationship between the depth H1 and the depth H2, and the relationship between the width W1 and the width W3 are adjusted such that desired electrical characteristics are obtained between a signal connection terminal 7 and a waveguide path 201.

The semiconductor module according to the fourteenth embodiment also achieves similar effects to those of the semiconductor module according to the thirteenth embodiment.

### Fifteenth Embodiment

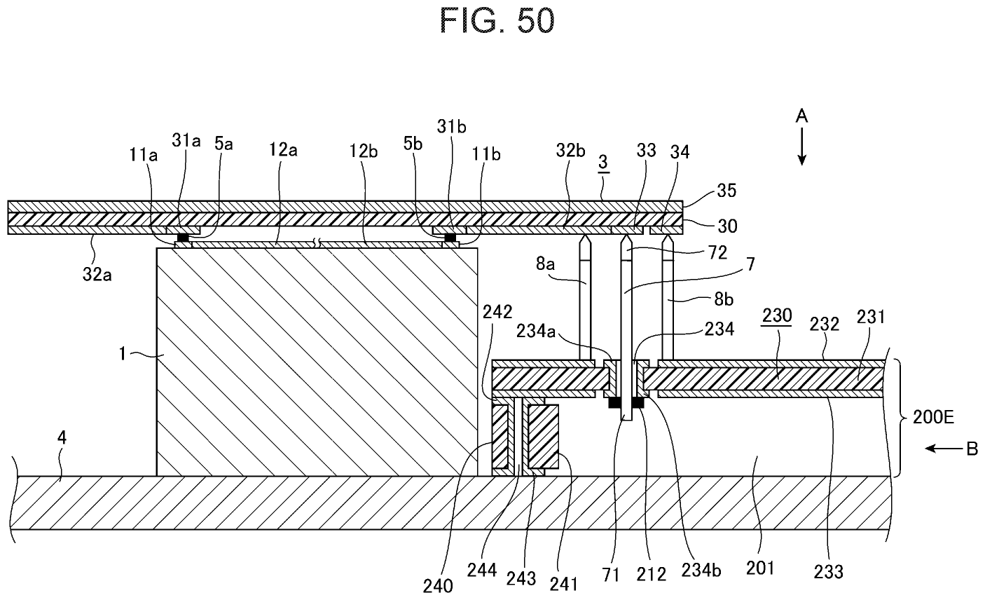

A semiconductor module according to a fifteenth embodiment will be described with reference to FIGS. 50 to 52.

The semiconductor module according to the fifteenth embodiment is different from the semiconductor module according to the seventh embodiment, in which a waveguide is used as the transmission line body 200, in that a hollow SIW, which is a type of dielectric substrate integrated waveguide (substrate integrated waveguide, hereinafter referred to as SIW) and is obtained by making a via in a dielectric substrate and causing a signal to be propagated in a waveguide mode, is used as a transmission line body 200E, and the other components are the same.

Note that in FIG. 50 the same symbols as those in FIGS. 23 and 38 denote the same or corresponding parts.

The transmission line body 200E includes a side wall body 240 and a conductor upper wall 230.

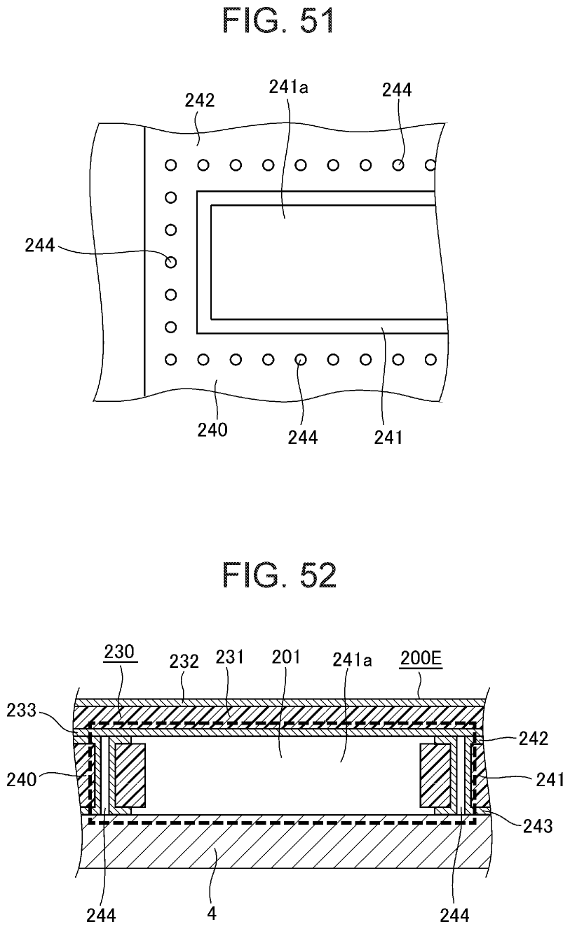

As illustrated in FIGS. 50 and 51, the side wall body 240 includes a dielectric substrate 241 having a cutout portion 241a opened at a second end and cut out from a front face to a back face, ground conductors 242 and 243 formed on the front face and the back face of the dielectric substrate, respectively, and a plurality of vias 244 arranged to surround the cutout portion 241a around the cutout portion 241a of the dielectric substrate 241, each of the vias 244 penetrating from the front face to the back face of the dielectric substrate 241 and electrically connecting the ground conductors 242 and 243 on the front face and the back face of the dielectric substrate 241.

The plurality of vias 244 function as pseudo conductor walls in the side wall.

The plurality of vias 244 may be through-vias or filling lid-plated vias.

A side wall body 240 is formed as a part of a printed board.

The ground conductor 243 formed on the back face of the dielectric substrate 241 in the side wall body 240 is in close contact with a front face of a heat dissipation plate 4.

The conductor upper wall 230 includes an upper wall substrate 231 made of a dielectric and ground conductors 232 and 233 on a front face and a back face of the upper wall substrate 231, respectively.

In the conductor upper wall 230, the ground conductors 232 and 233 are electrically connected by a plurality of vias penetrating from the front face to the back face of the upper wall substrate 231.

The conductor upper wall 230 covers a front face of the cutout portion 241a of the side wall body 240, and the ground conductor 233 formed on the back face of the conductor upper wall 230 and the ground conductor 242 formed on the front face of the dielectric substrate 241 in the side wall body 240 are fixed by a conductive adhesive such as solder.

A region (portion surrounded by a dotted line in FIG. 52) surrounded by the ground conductor 233 on the back face of the upper wall substrate 231, the plurality of vias 244 of the side wall body 240, and the front face of the heat dissipation plate 4 forms a waveguide path 201 in which a first end is short-circuited and a second end is opened.

On the first end side of the waveguide path 201, there is a feeding portion for a high-frequency signal of the waveguide path 201.

This feeding portion is a signal transmission portion of the transmission line body 200E.

The conductor upper wall 230 has a terminal insertion hole 234 by a through-via at a position corresponding to the feeding portion for the high-frequency signal of the waveguide path 201.

The through-via which is the terminal insertion hole 234 has a land electrically and physically separated from the ground conductor 232 on a front face of the conductor upper wall 230 and a land electrically and physically separated from the ground conductor 233 on the back face of the conductor upper wall 230.

The signal connection terminal 7 is fixed to the conductor upper wall 230 with a rear end of a fixed portion 71 located at a second end inserted in the terminal insertion hole 234 and with the rear end bonded to the land with a conductive adhesive 212.

A portion of the fixed portion 71 of the signal connection terminal 7 inserted in the waveguide path 201 functions as a feeding pin to feed, to the feeding portion, the high-frequency signal of the waveguide path 201 in the transmission line body 200A.

The plurality of ground connection terminals 8a to 8f is arranged concentrically about the signal connection terminal 7 to surround the signal connection terminal 7, and rear ends of fixed portions 8a1 to 8f1 located at second ends are electrically and mechanically connected to a front face of the ground conductor 232 of the conductor upper wall 230.

The periphery on the front face of the ground conductor 232 of the conductor upper wall 230 surrounding the signal connection terminal 7 serves as a ground portion.

Note that, in the conductor upper wall 230, vias 235a to 235f may be formed, the vias 235a to 235f arranged between the terminal insertion hole 234 and the plurality of ground connection terminals 8a to 8f to surround the terminal insertion hole 234 concentrically with the terminal insertion hole 234 in the center and electrically connecting the ground conductors 232 and 233, and a pseudo coaxial line may be included in which the through-via which is the terminal insertion hole 234 serves as an inner conductor and the vias 235a to 235f serve as outer conductors.

Also in the semiconductor module according to the fifteenth embodiment, as described in the semiconductor module according to the seventh embodiment, the shape of the waveguide path 201 may be any of a shape having a constant width from a first end to an open end, a shape having a tapered portion on the first end side, and a shape having a stepped portion on the first end side.

Moreover, also in the semiconductor module according to the fifteenth embodiment, as described in the semiconductor module according to the eighth embodiment, a conductor plate 73 may be attached to the fixed portion 71 of the signal connection terminal 7.

Furthermore, also in the semiconductor module according to the fifteenth embodiment, as described in the semiconductor module according to the ninth embodiment, a metal column 74 mounted in a heat dissipation plate 4C may be included, the metal column 74 having a distal end positioned inside the waveguide path 201 and facing the fixed portion 71 of the signal connection terminal 7.

Furthermore, also in the semiconductor module according to the fifteenth embodiment, as described in the semiconductor module according to the twelfth embodiment, a plurality of through-vias 236a to 236f may be formed in the conductor upper wall 230a of the transmission line body 200E in correspondence with the plurality of ground connection terminals 8a to 8f, and the plurality of ground connection terminals 8a to 8f may be inserted through the respective through-vias 236a to 236f at rear ends of fixed portions 8a1 to 8f1 positioned at second ends thereof and be electrically and mechanically connected to a front face of the ground conductor 233 of the conductor upper wall 230a by conductive adhesives 237a to 237f such as solder at the rear ends.

The semiconductor module according to the fifteenth embodiment also achieves similar effects to those of the semiconductor module according to the seventh embodiment.

Moreover, since the semiconductor module according to the fifteenth embodiment uses the hollow SIW in which a via is formed in the dielectric substrate and a signal is propagated in the waveguide mode, the semiconductor module includes basically the dielectric substrate and can be manufactured at low cost without requiring cutting processing while implementing a similar configuration to that of a normal waveguide.

Moreover, a chip component such as a chip capacitor can be mounted on a portion not used as the waveguide path, and thus a signal line such as another microstrip line can be formed, whereby a highly dense configuration can be implemented.

### Sixteenth Embodiment

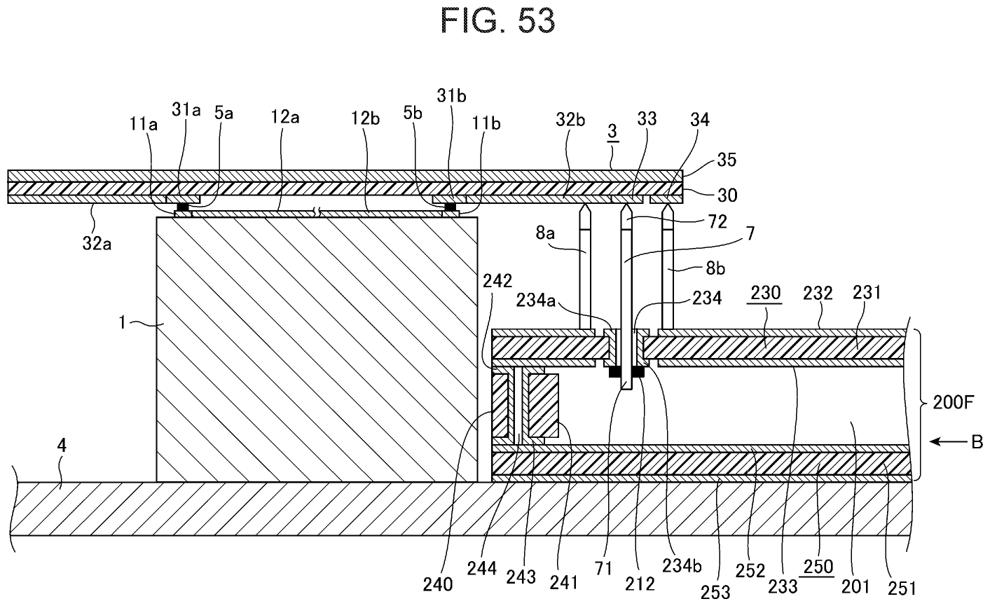

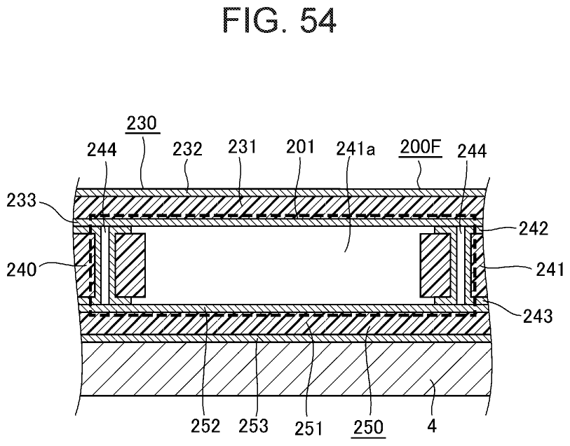

A semiconductor module according to a sixteenth embodiment will be described with reference to FIGS. 53 and 54.

A transmission line body 200F in the semiconductor module according to the sixteenth embodiment is different from the transmission line body 200E in the semiconductor module according to the fifteenth embodiment, the transmission line body 200E including the side wall body 240 and the conductor upper wall 230, in that the transmission line body 200F includes a side wall body 240, a conductor upper wall 230, and a conductor lower wall 250, and the other components are the same.

Note that in FIGS. 53 and 54 the same symbols as those in FIGS. 50 and 52 denote the same or corresponding parts.

The conductor lower wall 250 includes a lower wall substrate 251 made of a dielectric and ground conductors 252 and 253 on a front face and a back face of the lower wall substrate 251, respectively.

In the conductor lower wall 250, the ground conductors 252 and 253 are electrically connected by a plurality of vias penetrating from the front face to the back face of the lower wall substrate 251.

The conductor lower wall 250 covers a back face of a cutout portion 241a of a side wall body 240, and the ground conductor 252 formed on the front face of the conductor lower wall 250 and a ground conductor 243 formed on a back face of the dielectric substrate 241 in the side wall body 240 are fixed by a conductive adhesive such as solder.

The ground conductor 253 formed on the back face of the conductor lower wall 250 is in close contact with a front face of a heat dissipation plate 4.

A region (portion surrounded by a dotted line in FIG. 54) surrounded by a top face of the heat dissipation plate 4, the ground conductor 233 on the back face of the upper wall substrate 231, a plurality of vias 244 of the side wall body 240, and the ground conductor 252 formed on the front face of the conductor lower wall 250 forms a waveguide path 201 in which a first end is short-circuited and a second end is opened.

The semiconductor module according to the sixteenth embodiment also achieves similar effects to those of the semiconductor module according to the fifteenth embodiment.

### Seventeenth Embodiment

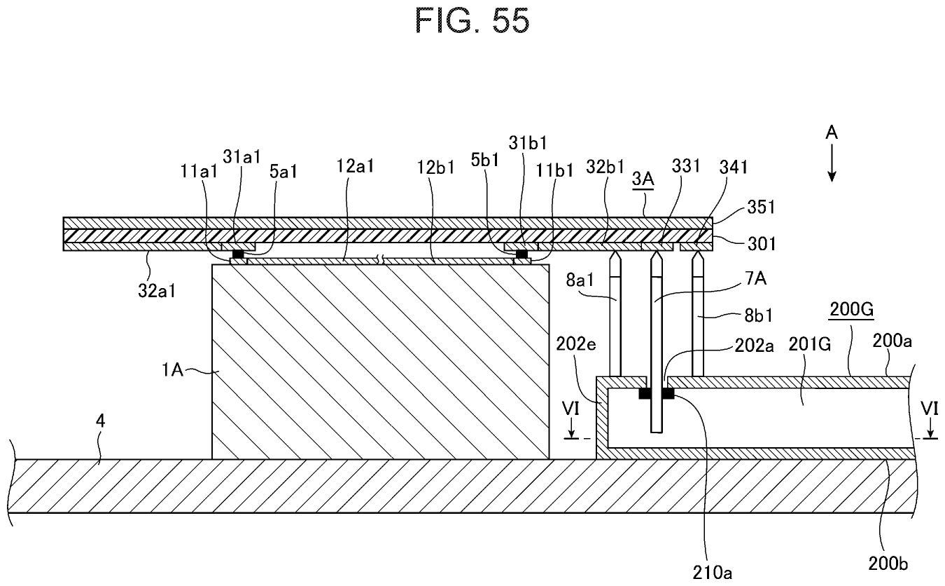

A semiconductor module according to a seventeenth embodiment will be described with reference to FIGS. 55 to 59.

The semiconductor module according to the seventeenth embodiment is obtained by, using four high-frequency power-amplification semiconductor elements 1A to 1D as a semiconductor element 1, applying the relationship among the semiconductor element 1, the transmission line body 200, the interposer substrate 3, and the heat dissipation plate 4 in the semiconductor module according to the seventh embodiment, in particular, the transmission path of a high-frequency signal, which is connected from the output signal terminal 11b of the semiconductor element 1 to the feeding portion for the high-frequency signal of the waveguide path 201, which is the signal transmission portion of the transmission line body 200, via the output-side semiconductor-element signal pad 31b, the output-side signal line 32b, and the transmission-line-body signal pad 33 of the interposer substrate 3 by the pseudo coaxial line including the signal connection terminal 7 and the plurality of ground connection terminals 8a to 8f, to a high-frequency high-power amplifier module that performs power combining of high-frequency output of the four high-frequency power-amplification semiconductor elements 1A to 1D.

As the semiconductor element, the first to fourth high-frequency power-amplification semiconductor elements 1A to 1D are included.

The first to fourth high-frequency power-amplification semiconductor elements 1A to 1D have, on a front face thereof, input signal terminals 11a1 to 11a4, output signal terminals 11b1 to 11b4, input signal lines 12a1 to 12a4 connected to the input signal terminals 11a1 to 11a4, output signal lines 12b1 to 12b4 connected to the output signal terminals 11b1 to 11b4, and four ground terminals 13a1 to 13a4, 13b1 to 13b4, 13c1 to 13c4, and 13d1 to 13d4.

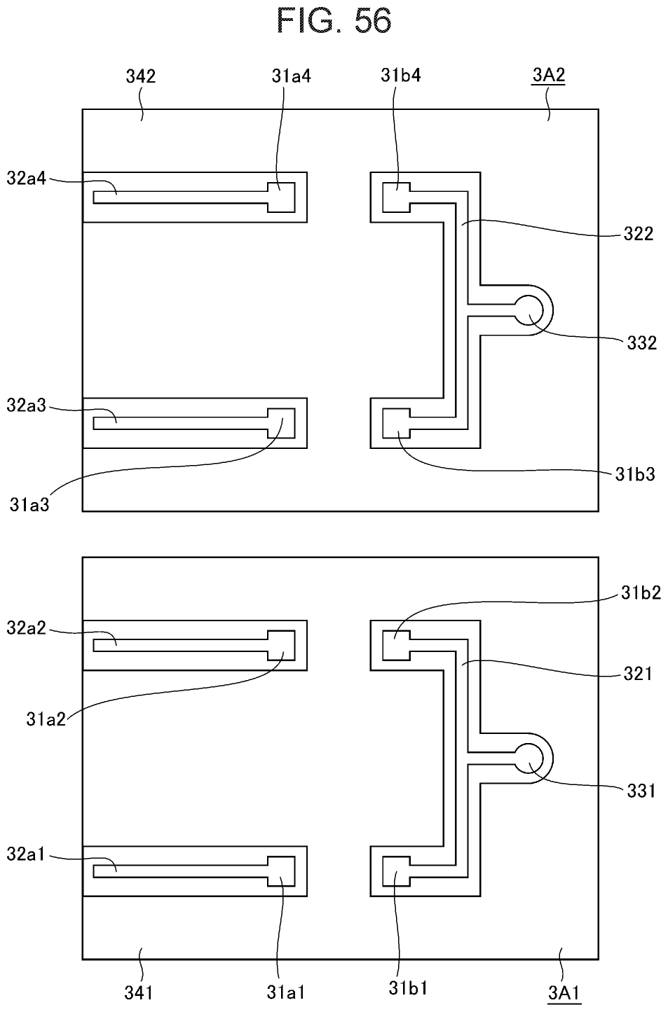

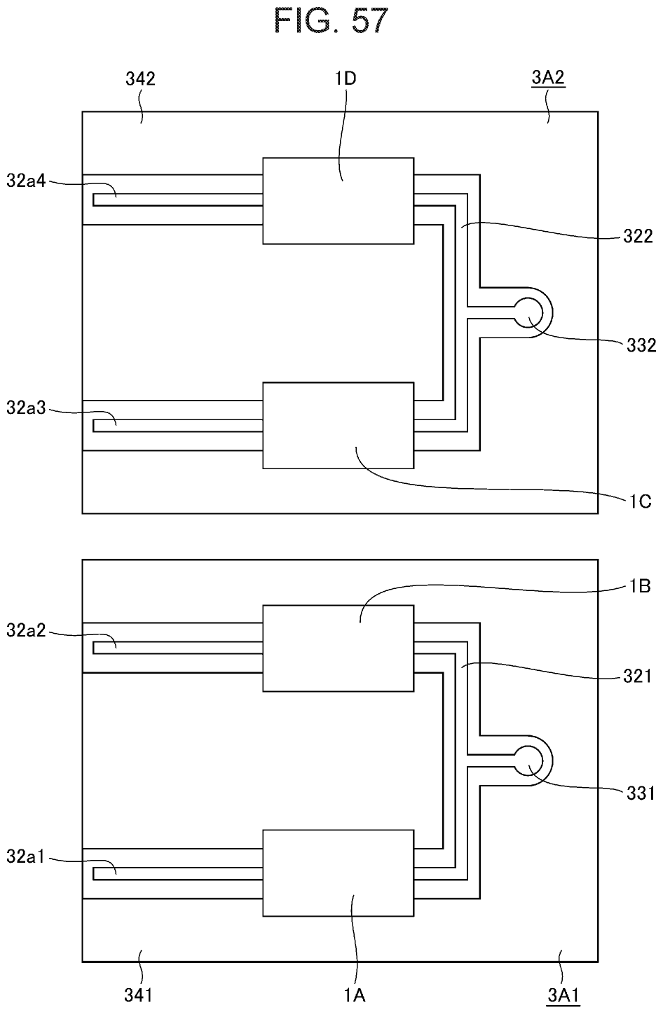

As illustrated in FIGS. 56 and 57, an interposer substrate 3A includes, as input-side semiconductor-element signal pads and output-side semiconductor-element signal pads, first to fourth output-side pads 31a1 to 31a4 and first to fourth amplified-signal input-side pads 31b1 to 31b4 corresponding to input signal terminals 11a1 to 11a4 and output signal terminals 11b1 to 11b4, respectively, of the first to fourth high-frequency power-amplification semiconductor elements 1A to 1D.

The interposer substrate 3A includes a first amplified-signal output-side pad 331 and a second amplified-signal output-side pad 332 as transmission-line-body signal pads and includes a first synthesis signal line 321 that connects the first amplified-signal input-side pad 31b1 and the second amplified-signal input-side pad 31b2 with the first amplified-signal output-side pad and a second synthesis signal line 322 that connects the third amplified-signal input-side pad 31b3 and the fourth amplified-signal input-side pad 31b4 with the second amplified-signal output-side pad.

The interposer substrate 3A includes two interposer substrates 3A1 and 3A2.

As illustrated in FIG. 57, the interposer substrate 3A1 includes the first output-side pad 31a1 and the second output-side pad 31a2, a first input-side signal line 32a1 and a second input-side signal line 32a2 connected to the first output-side pad 31a1 and the second output-side pad 31a2, respectively, the first amplified-signal input-side pad 31b1 and the second amplified-signal input-side pad 31b2, the first amplified-signal output-side pad 331, the first synthesis signal line 321, and a ground portion 341 that is a ground conductor on a front face of a dielectric substrate 301 and includes a ground layer 351 that is a ground conductor on a back face of the dielectric substrate 301.

Each of the first input-side signal line 32a1, the second input-side signal line 32a2, and the first synthesis signal line 321 functions as a transmission line of a microstrip line.

The interposer substrate 3A1 constitutes a power combining circuit of a high-frequency signal from the first high-frequency power-amplification semiconductor element 1A and a high-frequency signal from the second high-frequency power-amplification semiconductor element 1B.

As illustrated in FIG. 57, the interposer substrate 3A2 includes a third output-side pad 31a3 and a fourth output-side pad 31a4, a third input-side signal line 32a3 and a fourth input-side signal line 32a4 connected to the third output-side pad 31a3 and the fourth output-side pad 31a4, respectively, a third amplified-signal input-side pad 31b3 and a fourth amplified-signal input-side pad 31b4, a second amplified-signal output-side pad 332, a second synthesis signal line 322, and a ground portion 342 that is a ground conductor on the front face of the dielectric substrate 302, and includes a ground layer 352 that is a ground conductor on the back face of the dielectric substrate 302.

Each of the third input-side signal line 32a3, the fourth input-side signal line 32a4, and the second synthesis signal line 322 functions as a transmission line of a microstrip line.

The interposer substrate 3A2 constitutes a power combining circuit of a high-frequency signal from the third high-frequency power-amplification semiconductor element 1C and a high-frequency signal from the fourth high-frequency power-amplification semiconductor element 1D.

As illustrated in FIG. 57, the first high-frequency power-amplification semiconductor element 1A and the second high-frequency power-amplification semiconductor element 1B are electrically connected to a set of the first output-side pad 31a1 and the second output-side pad 31a2 and a set of the first amplified-signal input-side pad 31b1 and the second amplified-signal input-side pad 31b2 of the first interposer substrate 3A1, respectively, to which a set of the input signal terminal 11a1 and the input signal terminal 11a2 and a set of the output signal terminal 11b and the output signal terminal 11b2 correspond, respectively, by conductive adhesives Sal, 5a2, 5b1, and 5b2 such as solder balls

The ground terminals 13a1 to 13d1 and 13a2 to 13d2 of the first high-frequency power-amplification semiconductor element 1A and the second high-frequency power-amplification semiconductor element 1B are electrically connected to the ground portion 341 of the interposer substrate 3A1 by conductive adhesives 6a1 to 6d1 and 6a2 to 6d2, respectively, such as solder balls.

As a result, the first high-frequency power-amplification semiconductor element 1A and the second high-frequency power-amplification semiconductor element 1B are mounted on the first interposer substrate 3A1.

As illustrated in FIG. 57, the third high-frequency power-amplification semiconductor element 1C and the fourth high-frequency power-amplification semiconductor element 1D are electrically connected to a set of the third output-side pad 31a3 and the fourth output-side pad 31a4 and a set of the third amplified-signal input-side pad 31b3 and the fourth amplified-signal input-side pad 31b4 of the second interposer substrate 3A2, respectively, to which a set of the input signal terminal 11a3 and the input signal terminal 11a4 and a set of the output signal terminal 11b3 and the output signal terminal 11b4 correspond, respectively, by conductive adhesives 5a3, 5a4, 5b3, and 5b4 such as solder balls

The ground terminals 13a3 to 13d3 and 13a4 to 13d4 of the third high-frequency power-amplification semiconductor element 1C and the fourth high-frequency power-amplification semiconductor element 1D are electrically connected to the ground portion 341 of the interposer substrate 3A1 by conductive adhesives 6a3 to 6d3 and 6a4 to 6d4, respectively, such as solder balls.

As a result, the third high-frequency power-amplification semiconductor element 1C and the fourth high-frequency power-amplification semiconductor element 1D are mounted on the second interposer substrate 3A2.

Note that the first interposer substrate 3A1 and the second interposer substrate 3A2 may be integrated into a single interposer substrate.

A signal connection terminal includes a first signal connection terminal 7A and a second signal connection terminal 7B.

As illustrated in FIG. 10, each of the first signal connection terminal 7A and the second signal connection terminal 7B is a spring structure terminal, such as a spring probe, having a fixed portion 71 and a movable portion 72 at a distal end and as illustrated by an arrow B, the movable portion 72 extends and contracts in the up-down direction in the drawing with respect to the fixed portion 71.

Note that each of the first signal connection terminal 7A and the second signal connection terminal 7B may have a structure illustrated in FIG. 12.

When a front face of the first interposer substrate 3A on which the first high-frequency power-amplification semiconductor element 1A and the second high-frequency power-amplification semiconductor element 1B are mounted is disposed to face a front face of the heat dissipation plate 4, a distal end of the movable portion 72 of the first signal connection terminal 7A is in contact with and pressed against the first amplified-signal output-side pad 331 formed on the front face of the first interposer substrate 3A, and the movable portion 72 of the first signal connection terminal 7A moves toward the fixed portion 71.

As a result, the first amplified-signal output-side pad 331 is brought into close contact with the distal end of the movable portion 72 of the first signal connection terminal 7A in a state where pressure is applied to the distal end.

When a front face of the second interposer substrate 3B on which the third high-frequency power-amplification semiconductor element 1C and the fourth high-frequency power-amplification semiconductor element 1D are mounted is disposed to face the front face of the heat dissipation plate 4, a distal end of the movable portion 72 of the second signal connection terminal 7B is in contact with and pressed against the second amplified-signal output-side pad 332 formed on the front face of the second interposer substrate 3B, and the movable portion 72 of the second signal connection terminal 7B moves toward the fixed portion 71.

As a result, the second amplified-signal output-side pad 332 is brought into close contact with the distal end of the movable portion 72 of the second signal connection terminal 7B in a state where pressure is applied to the distal end.

In a transmission line body 200G, a signal transmission portion includes: a first signal input portion to which the fixed portion 71 of the first signal connection terminal 7A is electrically connected and a second signal input portion to which the fixed portion 71 of the second signal connection terminal 7B is electrically connected; and a synthesis path that combines a high-frequency signal input to the first signal input portion and a high-frequency signal input to the second signal input portion.

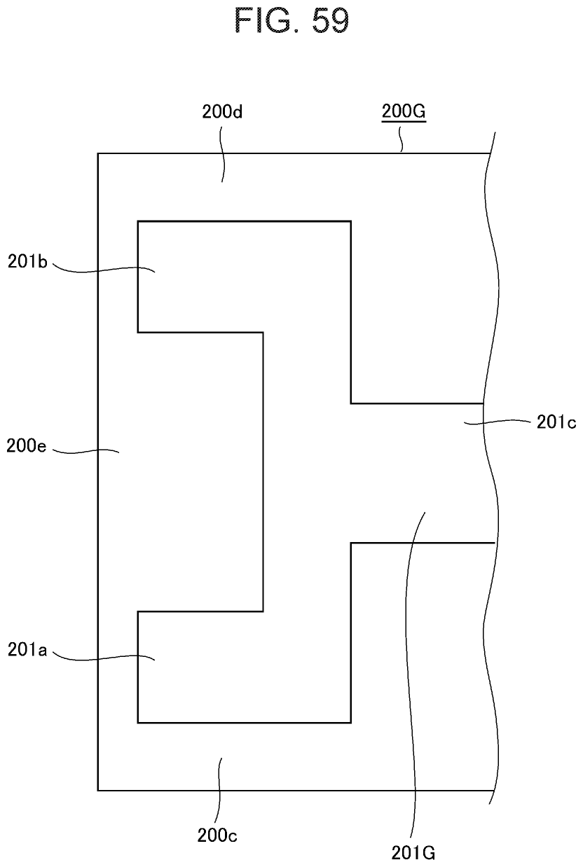

As illustrated in FIGS. 55 and 59, the transmission line body 200G is a waveguide made of a conductor, the waveguide having an upper wall 200a, a lower wall 200b, both side walls 200c and 200d, and a first end wall 200e.

Hereinafter, to facilitate understanding of the description, the transmission line body 200G will be described as a waveguide 200G.

A synthesis path 201G in the waveguide 200G includes a first waveguide path 201a having a first end short-circuited, a second waveguide path 201b having a first end short-circuited, and a synthesis waveguide path 201c having a first end communicating with a second end of the first waveguide path 201a and a second end of the second waveguide path 201b and having a second end opened, which are formed in a space surrounded by inner faces of the upper wall 200a, the lower wall 200b, both the side walls 200c and 200d, and a first end wall 200e.

The shapes of the first waveguide path 201a, the second waveguide path 201b, and the synthesis waveguide path 201c in the synthesis path 201G each have a rectangular cross-section having a constant width from the first end to the second end.

Note that each of the first waveguide path 201a and the second waveguide path 201b in the synthesis path 201G may have a tapered portion or a stepped portion that becomes narrow from the first end and have a constant width continuously from the tapered portion or the stepped portion to the second end, and the synthesis waveguide path 201c in the synthesis path 201G may have a shape with a constant width from the first end to the second end.

On the first end wall 200e side of the first waveguide path 201a, there is a feeding portion for a high-frequency signal of the first waveguide path 201a that is a first signal input portion in the signal transmission portion of the transmission line body 200G.

On the first end wall 200e side of the second waveguide path 201b, there is a feeding portion for a high-frequency signal of the second waveguide path 201b that is a second signal input portion in the signal transmission portion of the transmission line body 200G.

In addition, the first end wall 200e of the waveguide 200G is short-circuited. That is, an inner face of the first end wall 200e of the waveguide 200G is a short-circuit plane.

The high-frequency signal input to the feeding portion for a high-frequency signal of the first waveguide path 201a and the high-frequency signal input to the feeding portion for a high-frequency signal of the second waveguide path 201b are combined by the synthesis waveguide path 201c in the signal transmission portion.

The waveguide 200G constitutes a power combining circuit that combines the combined high-frequency signal fed to the first waveguide path 201a of the waveguide 200G and the combined high-frequency signal fed to the second waveguide path 201b of the waveguide 200G.

The waveguide 200G has, in the upper wall 200a, a first terminal insertion hole 202a, into which the rear end of the fixed portion 71 positioned at the second end of the first signal connection terminal 7A is inserted, at a position corresponding to the feeding portion for the high-frequency signal in the first waveguide path 201a and has, in the upper wall 200a, a second terminal insertion hole 202b, into which the rear end of the fixed portion 71 positioned at the second end of the second signal connection terminal 7B is inserted, at a position corresponding to the feeding portion for the high-frequency signal in the second waveguide path 201b.

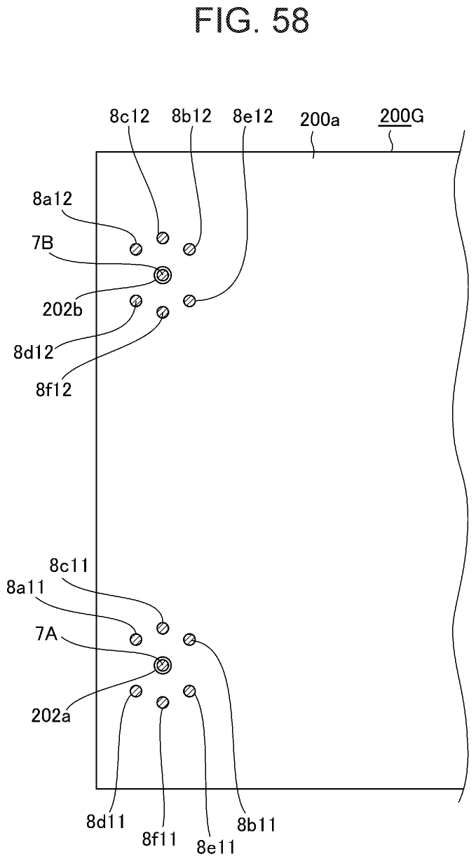

As illustrated in FIGS. 55 and 58, the first signal connection terminal 7A of the signal connection terminal is inserted in the first terminal insertion hole 202a at the rear end of the fixed portion 71 located at the second end by the length y1 similarly to FIG. 24 and is fixed to the inner face of the upper wall 200a of the waveguide 200G by an insulating adhesive 210a at the rear end.

A portion of the fixed portion 71 of the first signal connection terminal 7A inserted in the first waveguide path 201a functions as a feeding pin to feed, to the feeding portion, the high-frequency signal of the first waveguide path 201a.

As illustrated in FIGS. 55 and 58, the second signal connection terminal 7B of the signal connection terminal is inserted in the second terminal insertion hole 202b at the rear end of the fixed portion 71 located at the second end by the length y1 similarly to FIG. 24 and is fixed to the inner face of the upper wall 200a of the waveguide 200G by an insulating adhesive 210b at the rear end.

A portion of the fixed portion 71 of the second signal connection terminal 7B inserted in the second waveguide path 201b functions as a feeding pin to feed, to the feeding portion, the high-frequency signal of the second waveguide path 201b.

As illustrated in FIG. 58, a plurality of first ground connection terminals 8a11 to 8f11 is arranged to surround the first signal connection terminal 7A and constitute a pseudo coaxial line together with the first signal connection terminal 7A.

As illustrated in FIG. 58, the plurality of first ground connection terminals 8a11 to 8f11 is arranged concentrically about the first signal connection terminal 7A to surround the first signal connection terminal 7A, and rear ends of fixed portions 8a1 to 8f1 located at second ends are electrically and mechanically connected to a front face of the upper wall 200a of the waveguide 200G.

The periphery on the front face of the upper wall 200a of the waveguide 200G surrounding the first signal connection terminal 7A serves as a ground portion.

As illustrated in FIG. 58, a plurality of second ground connection terminals 8a12 to 8f12 is arranged to surround the second signal connection terminal 7B and constitute a pseudo coaxial line together with the second signal connection terminal 7B.

As illustrated in FIG. 58, the plurality of second ground connection terminals 8a12 to 8f12 is arranged concentrically about the second signal connection terminal 7B to surround the second signal connection terminal 7B, and rear ends of fixed portions 8a1 to 8f1 located at second ends are electrically and mechanically connected to a front face of the upper wall 200a of the waveguide 200G.

The periphery on the front face of the upper wall 200a of the waveguide 200G surrounding the second signal connection terminal 7B serves as a ground portion.

When the front face of the first interposer substrate 3A on which the first high-frequency power-amplification semiconductor element 1A and the second high-frequency power-amplification semiconductor element 1B are mounted is disposed to face the front face of the heat dissipation plate 4, distal ends of movable portions 8a2 to 8f2 of the respective first ground connection terminals 8a11 to 8f11 come into contact with and are pressed against the ground portion 341 formed on the front face of the first interposer substrate 3A, and the movable portions 8a2 to 8f2 of the respective first ground connection terminals 8a11 to 8f11 move toward the fixed portions 8a1 to 8f1.

As a result, the ground portion 341 is brought into close contact with the distal ends of the movable portions 8a2 to 8f2 of the plurality of first ground connection terminals 8a11 to 8f11, respectively, in a state where pressure is applied to the distal ends.

When the front face of the second interposer substrate 3B on which the third high-frequency power-amplification semiconductor element 1C and the fourth high-frequency power-amplification semiconductor element 1D are mounted is disposed to face the front face of the heat dissipation plate 4, distal ends of movable portions 8a2 to 8f2 of the respective second ground connection terminals 8a12 to 8f12 come into contact with and are pressed against the ground portion 342 formed on the front face of the second interposer substrate 3B, and the movable portions 8a2 to 8f2 of the respective second ground connection terminals 8a12 to 8f12 move toward the fixed portions 8a1 to 8f1.

As a result, the ground portion 342 is brought into close contact with the distal ends of the movable portions 8a2 to 8f2 of the plurality of second ground connection terminals 8a12 to 8f12, respectively, in a state where pressure is applied to the distal ends.

In the semiconductor module according to the seventeenth embodiment, the first high-frequency power-amplification semiconductor element 1A and the second high-frequency power-amplification semiconductor element 1B are flip-chip mounted on the front face of the first interposer substrate 3A, the third high-frequency power-amplification semiconductor element 1C and the fourth high-frequency power-amplification semiconductor element 1D are flip-chip mounted on the front face of the second interposer substrate 3B, and then the first interposer substrate 3A, on which the first high-frequency power-amplification semiconductor element 1A and the second high-frequency power-amplification semiconductor element 1B are mounted, and the second interposer substrate 3B, on which the third high-frequency power-amplification semiconductor element 1C and the fourth high-frequency power-amplification semiconductor element 1D are mounted, are arranged to face the front face of the heat dissipation plate 4, and the first interposer substrate 3A and the second interposer substrate 3B are pressed against the heat dissipation plate 4 in the direction of the arrow A illustrated in FIG. 55 in such a manner that the back faces of the first to fourth high-frequency power-amplification semiconductor elements 1A to 1D are in close contact with the front face of the heat dissipation plate 4.

As a result, the high-frequency signals from the first high-frequency power-amplification semiconductor element 1A and the second high-frequency power-amplification semiconductor element 1B are power-combined by the first interposer substrate 3A, and the power-combined high-frequency signal is fed to the first waveguide path 201a of the waveguide 200G by the pseudo coaxial line by the first signal connection terminal 7A and the plurality of first ground connection terminals 8a11 to 8f11.

In addition, the high-frequency signals from the third high-frequency power-amplification semiconductor element 1C and the fourth high-frequency power-amplification semiconductor element 1D are power-combined by the second interposer substrate 3B, and the power-combined high-frequency signal is fed to the second waveguide path 201b of the waveguide 200G by the pseudo coaxial line by the second signal connection terminal 7B and the plurality of second ground connection terminals 8a12 to 8f12.

The combined high-frequency signal fed to the first waveguide path 201a of the waveguide 200G and the combined high-frequency signal fed to the second waveguide path 201b of the waveguide 200G are further combined by the synthesis waveguide path 201c of the waveguide 200G.

Also in the semiconductor module according to the seventeenth embodiment, similarly to the semiconductor module according to the seventh embodiment, firstly, the influence of parasitic inductance and degradation of electrical characteristics can be reduced, secondly, since the pseudo coaxial line constituted by the first signal connection terminal 7A and the plurality of first ground connection terminals 8a11 to 8f11 and the pseudo coaxial line constituted by the second signal connection terminal 7B and the plurality of second ground connection terminals 8a12 to 8f12 include a connection terminal having a movable portion, it is possible to surely assemble, to ensure electrical connection, and to perform reliable high-frequency signal transmission even if there is a tolerance, namely, a level difference in the thickness direction of the semiconductor element 1 and the transmission line body 2, and thirdly, it is possible to stably mount, on the heat dissipation plate 4, the first interposer substrate 3A on which the first high-frequency power-amplification semiconductor element 1A and the second high-frequency power-amplification semiconductor element 1B are mounted, the second interposer substrate 3B on which the third high-frequency power-amplification semiconductor element 1C and the fourth high-frequency power-amplification semiconductor element 1D are mounted, and the waveguide 200G. Fourthly, it is possible to reduce the thermal resistance between the back faces of the first high-frequency power-amplification semiconductor element 1A to the fourth high-frequency power-amplification semiconductor element 1D and the front face of the heat dissipation plate 4 and to efficiently dissipate, by the heat dissipation plate 4, the heat generated by the first high-frequency power-amplification semiconductor element 1A to the fourth high-frequency power-amplification semiconductor element 1D, fifthly, the withstand power as the transmission line body 200G for high-frequency signal is improved, thereby contributing to an increase in power as the high frequency module, and sixthly, the downsize effect is achieved as compared to that in which the first interposer substrate 3A, the second interposer substrate 3B, and the transmission line body 200G that is a waveguide are arranged in the horizontal direction.

Furthermore, since the high-frequency amplified signals of the first to fourth high-frequency power-amplification semiconductor elements 1A to 1D are power-combined by the first interposer substrate 3A, the second interposer substrate 3B, and the transmission line body 200G that is a waveguide, the semiconductor module according to the seventeenth embodiment is improved in high power durability, power loss, and withstand power of the transmission line body 200G.

In addition, since both the first interposer substrate 3A and the second interposer substrate 3B include a microstrip line, the semiconductor module has wavelength shortening effect associated with dielectric constants of the dielectric substrate 301 and the dielectric substrate 302, and is improved in size.

In short, since the power combining at the preceding stage with small power is performed by the power combining circuit formed on the first interposer substrate 3A and the second interposer substrate 3B, the semiconductor module is improved in densification, and since the power combining at the subsequent stage with large power is performed by the power combining circuit formed on the transmission line body 200G which is a waveguide, the semiconductor module is improved in power durability, a high-frequency high-power amplifier module reduced in size, and improved in power durability, and enhanced in heat dissipation performance can be obtained.

Note that, in the semiconductor module according to the seventeenth embodiment, the four high-frequency power-amplification semiconductor elements 1A to 1D are used as the semiconductor elements 1, however, this is not limited to four high-frequency power-amplification semiconductor elements, and this is applicable to a plurality of high-frequency power-amplification semiconductor elements.

Each of the first interposer substrate 3A and the second interposer substrate 3B is a power combining circuit that combines high-frequency amplified signals from two high-frequency power-amplification semiconductor elements but may be another power combining circuit such as a power combining circuit that combines high-frequency amplified signals from four high-frequency power-amplification semiconductor elements depending on specifications.

Note that the power combining circuit including the first interposer substrate 3A and the second interposer substrate 3B may have a configuration such as a Wilkinson power combining circuit or a Gysel power combining circuit mounted with a chip resistor, a thin film resistor, or the like.

Although the waveguide 200G is a power combining circuit that combines the two combined high-frequency signals from the first interposer substrate 3A and the second interposer substrate 3B but may be another power combining circuit such as a power combining circuit that combines four combined high-frequency signals depending on the configuration of the power combining circuit in an interposer substrate.

Note that the power combining circuit by the waveguide 200G may have a configuration such as the Magic T including a plurality of branching portions.

Note that, in the semiconductor module according to the seventeenth embodiment, similarly to the semiconductor module according to the eighth embodiment, a first conductor plate may be attached to a portion of the fixed portion 71 of the first signal connection terminal 7A inserted inside the first waveguide path 201a in the synthesis path 201G, and a second conductor plate may be attached to a portion of the fixed portion 71 of the second signal connection terminal 7b inserted inside the second waveguide path 201b in the synthesis path 201G.

Furthermore, in the semiconductor module according to the seventeenth embodiment, similarly to the semiconductor module according to the ninth embodiment, the semiconductor module may include: a first metal column having a distal end positioned inside the first waveguide path 201a in the synthesis path 201G and facing the fixed portion 71 of the first signal connection terminal 7A, the first metal column mounted on the heat dissipation plate 4; and a second metal column having a distal end positioned inside the second waveguide path 201b in the synthesis path 201G and facing the fixed portion 71 of the second signal connection terminal 7B, the second metal column mounted on the heat dissipation plate 4.

Furthermore, similarly to the semiconductor module according to the eleventh embodiment, a waveguide having a conductor side wall and a conductor upper wall made of a conductor may be used as the transmission line body 200G.

That is, as the waveguide, the following configuration is included.

The conductor side wall includes a conductor having both side walls and a first end wall, and bottom faces of both the side walls and the first end wall are in close contact with the front face of the heat dissipation plate.

The conductor upper wall includes an upper wall substrate made of a dielectric and a ground conductor on each of a front face and a back face of the upper wall substrate.

A synthesis path in the waveguide includes a first waveguide path having a first end short-circuited, a second waveguide path having a first end short-circuited, and a synthesis waveguide path having a first end communicating with a second end of the first waveguide path and a second end of the second waveguide path and having a second end opened, which are formed in a space surrounded by inner faces of both of the side walls and the first end wall of the conductor side wall, the ground conductor on the back face of the upper wall substrate, and the front face of the heat dissipation plate.

The first signal input portion in the signal transmission portion of the transmission line body is the feeding portion for the high-frequency signal of the first waveguide path, and the second signal input portion in the signal transmission portion of the transmission line body is the feeding portion for the high-frequency signal of the second waveguide path.

The fixed portion of the first signal connection terminal in the signal connection terminal is inserted in the first terminal insertion hole in the upper wall of the waveguide formed at the position corresponding to the feeding portion for the high-frequency signal of the first waveguide path, and the portion inserted inside the first waveguide path functions as the feeding pin to feed, to the feeding portion, the high-frequency signal of the first waveguide path.

The fixed portion of the second signal connection terminal in the signal connection terminal is inserted in the second terminal insertion hole in the upper wall of the waveguide formed at the position corresponding to the feeding portion for the high-frequency signal of the second waveguide path, and the portion inserted inside the second waveguide path functions as the feeding pin to feed, to the feeding portion, the high-frequency signal of the second waveguide path.

The ground portion of the transmission line body is a periphery of the ground conductor on the front face of the upper wall substrate surrounding each of the first signal connection terminal and the second signal connection terminal in the signal connection terminal.

Furthermore, similarly to the semiconductor module according to the thirteenth embodiment, a waveguide having a waveguide groove to be included in the waveguide path formed in the heat dissipation plate that is a metal plate and a conductor upper wall made of a conductor may be used as the transmission line body 200G.

That is, as the waveguide, the following configuration is included.

The heat dissipation plate is a metal plate having the waveguide groove on a front face.

The transmission line body has the conductor upper wall.

The conductor upper wall includes an upper wall substrate made of a dielectric and a ground conductor on each of a front face and a back face of the upper wall substrate and covers the waveguide groove of the heat dissipation plate, and the ground conductor on the back face of the upper wall substrate is in close contact with the front face of the heat dissipation plate.

A synthesis path in the waveguide includes a first waveguide path having a first end short-circuited, a second waveguide path having a first end short-circuited, and a synthesis waveguide path having a first end communicating with a second end of the first waveguide path and a second end of the second waveguide path and having a second end opened, which are formed in a space surrounded by the ground conductor on the back face of the upper wall substrate and the waveguide groove of the heat dissipation plate.

The first signal input portion in the signal transmission portion of the transmission line body is the feeding portion for the high-frequency signal of the first waveguide path, and the second signal input portion in the signal transmission portion of the transmission line body is the feeding portion for the high-frequency signal of the second waveguide path.

The fixed portion of the first signal connection terminal in the signal connection terminal is inserted in the first terminal insertion hole in the conductor upper wall formed at the position corresponding to the feeding portion for the high-frequency signal of the first waveguide path, the conductor upper wall constituting the waveguide, and the portion inserted inside the first waveguide path functions as the feeding pin to feed, to the feeding portion, the high-frequency signal of the first waveguide path.

The fixed portion of the second signal connection terminal in the signal connection terminal is inserted in the second terminal insertion hole in the conductor upper wall formed at the position corresponding to the feeding portion for the high-frequency signal of the second waveguide path, the conductor upper wall constituting the waveguide, and the portion inserted inside the second waveguide path functions as the feeding pin to feed, to the feeding portion, the high-frequency signal of the second waveguide path.

The ground portion of the transmission line body is a periphery of the ground conductor on the front face of the upper wall substrate surrounding each of the first signal connection terminal and the second signal connection terminal in the signal connection terminal.

Furthermore, as the transmission line body 200G, similarly to the semiconductor module according to the fifteenth embodiment, a hollow SIW, which is a type of dielectric substrate integrated waveguide that is obtained by forming a via in a dielectric substrate and propagates a signal in a waveguide mode, may be used.

That is, the hollow SIW has the following configuration.

The transmission line body is the SIW including a side wall body and a conductor upper wall.

The side wall body includes a dielectric substrate having a cutout portion opened at a second end, ground conductors formed on a front face and a back face of the dielectric substrate, and a plurality of vias arranged around the cutout portion of the dielectric substrate to surround the cutout portion, each of the vias penetrating from the front face to the back face of the dielectric substrate, electrically connecting the ground conductors on the front face and the back face of the dielectric substrate, and functioning as a pseudo conductor wall.

The conductor upper wall includes an upper wall substrate made of a dielectric and a ground conductor on each of a front face and a back face of the upper wall substrate and covers the cutout portion of the side wall body, and the ground conductor on the back face of the upper wall substrate is in close contact with the ground conductor on the front face of the side wall body.

A synthesis path in the SIW includes a first waveguide path having a first end short-circuited, a second waveguide path having a first end short-circuited, and a synthesis waveguide path having a first end communicating with a second end of the first waveguide path and a second end of the second waveguide path and having a second end opened, which are formed in a region surrounded by the ground conductor on the back face of the upper wall substrate and the plurality of vias of the side wall body.

The first signal input portion in the signal transmission portion of the transmission line body is the feeding portion for the high-frequency signal of the first waveguide path, and the second signal input portion in the signal transmission portion of the transmission line body is the feeding portion for the high-frequency signal of the second waveguide path.

The fixed portion of the first signal connection terminal in the signal connection terminal is inserted in the first terminal insertion hole in the conductor upper wall formed at the position corresponding to the feeding portion for the high-frequency signal of the first waveguide path, the conductor upper wall constituting the transmission line body, and the portion inserted inside the first waveguide path functions as the feeding pin to feed, to the feeding portion, the high-frequency signal of the first waveguide path.

The fixed portion of the second signal connection terminal in the signal connection terminal is inserted in the second terminal insertion hole in the conductor upper wall formed at the position corresponding to the feeding portion for the high-frequency signal of the second waveguide path, the conductor upper wall constituting the transmission line body, and the portion inserted inside the second waveguide path functions as the feeding pin to feed, to the feeding portion, the high-frequency signal of the second waveguide path.

The ground portion of the transmission line body is a periphery of the ground conductor on the front face of the upper wall substrate surrounding each of the first signal connection terminal and the second signal connection terminal in the signal connection terminal.

Note that it is possible include a flexible combination of the embodiments, a modification of any component of the embodiments, or omission of any component in the embodiments.

### INDUSTRIAL APPLICABILITY

The semiconductor modules according to the present disclosure are suitable for a high-frequency high-power amplifier module, particularly for a high-frequency high-power amplifier module used for devices such as those for communication or radar.

### REFERENCE SIGNS LIST

1 and 1′: Semiconductor element, 1A to 1D: High-frequency power-amplification semiconductor element, 11a, and 11a1 to 11a4: Input signal terminal, 11b, and 11b1 to 11b4: Output signal terminal, 12a, and 12a1 to 12a4: Input signal line, 12b, and 12b1 to 12b4: Output signal line, 13a to 13d, 13a1 to 13d1, and 13a2 to 13d2: Ground terminal, 2, 2A to 2C, 200, and 200A to 200G: Transmission line body, 21: Signal transmission portion, 22: Ground portion, 23: Signal transmission line, 24: Ground layer, 201: Waveguide path, 201G: Synthesis path, 201a: First waveguide path, 201b: Second waveguide path, 201c: Synthesis waveguide path, 220: Conductor side wall, 230: Conductor upper wall, 240: Side wall body, 3, 3A, 3A1, and 3A2: Interposer substrate, 30, 301, and 302: Dielectric substrate, 31a: Input-side semiconductor-element signal pad, 31a1 to 31a4: Output-side pad, 31b: Output-side semiconductor-element signal pad, 31b1 to 31b4: Amplified-signal input-side pad, 32a: Input-side signal line, 32b: Output-side signal line, 33: Transmission-line-body signal pad, 331 and 332: Amplified-signal output-side pad, 34, 341, and 342: Ground portion, 35: Ground layer, 4, and 4A to 4C: Heat dissipation plate, 4A1: Protrusion, 4B1: Recessed portion, 4C1: Screw hole, 4D1: Waveguide groove, 41: Spacer, 5a, 5b, Sal, 5a2, 5b1, 5b2, 6a to 6d, 6a1 to 6d1, and 6a2 to 6d2: Conductive adhesive, 7, 7A, and 7B: Signal connection terminal, 72: Movable portion, 73: Conductor plate, 8a to 8f, 8a11 to 8f11, and 8a12 to 8f12: Ground connection terminal, 8a2 to 8f2: Movable portion, 9: Conductive adhesive

1. A semiconductor module comprising:
a semiconductor element having, on a front face thereof, a signal terminal and a ground terminal;
a transmission line body having a signal transmission portion and a ground portion;
a signal connection terminal having a movable portion at a first end thereof and a fixed portion located at a second end thereof and electrically connected to the signal transmission portion of the transmission line body;
a plurality of ground connection terminals arranged to surround the signal connection terminal, each of the ground connection terminals having a movable portion at a first end thereof, and a fixed portion located at a second end thereof and electrically connected to the ground portion of the transmission line body, the plurality of ground connection terminals and the signal connection terminal constituting a pseudo coaxial line;
a heat dissipation plate having a front face in close contact with a back face of the semiconductor element; and
an interposer substrate having a front face disposed to face the front face of the heat dissipation plate, the interposer substrate having, on the front face, a semiconductor-element signal pad electrically connected to the signal terminal of the semiconductor element by a conductive adhesive, a transmission-line-body signal pad in contact with the movable portion of the signal connection terminal and electrically connected to the signal connection terminal, and a ground portion in contact with the movable portions of the plurality of ground connection terminals and electrically connected to the plurality of ground connection terminals.

2. The semiconductor module according to claim 1, wherein
the semiconductor element is a power amplifier mounted with a plurality of active elements such as a high-frequency amplifier and a transistor or a semiconductor integrated circuit device mounted with a plurality of passive components.

3. The semiconductor module according to claim 1, wherein
the heat dissipation plate has a protrusion that is a portion where the back face of the semiconductor element is in close contact.

4. The semiconductor module according to claim 1, wherein
the transmission line body is a microstrip line having a dielectric substrate,
the signal transmission portion of the transmission line body is a signal pad formed on a front face of the dielectric substrate and connected to a signal transmission line formed on the front face of the dielectric substrate, and
the ground portion of the transmission line body is a ground conductor formed on the front face of the dielectric substrate and electrically separated from the signal transmission line body and the signal pad.

5. The semiconductor module according to claim 1, wherein
the transmission line body is a microstrip line having a dielectric substrate,
the signal transmission portion of the transmission line body is a signal pad formed on a back face of the dielectric substrate and connected to a signal transmission line formed on the back face of the dielectric substrate, and
the ground portion of the transmission line body is a ground conductor formed on the front face of the dielectric substrate.

6. The semiconductor module according to claim 1, wherein
the transmission line body is a microstrip line having a dielectric substrate,
the signal transmission portion of the transmission line body is a signal pad formed on the back face of the dielectric substrate and connected to a signal transmission line formed on the back face of the dielectric substrate, and
the ground portion of the transmission line body is a ground conductor formed on the back face of the dielectric substrate.

7. The semiconductor module according to claim 5, wherein
the heat dissipation plate includes a recessed portion physically separated from the signal transmission portion and the signal transmission line of the transmission line body on the front face to which the signal transmission portion and the signal transmission line of the transmission line body face.

8. The semiconductor module according to claim 5, further comprising:
a spacer between the back face of the transmission line body and the front face of the heat dissipation plate, the spacer surrounding the signal transmission portion and the signal transmission line of the transmission line body and physically separating the signal transmission portion and the signal transmission line of the transmission line body from the front face of the heat dissipation plate.

9. The semiconductor module according to claim 1, wherein
the transmission line body is a waveguide,
the signal transmission portion of the transmission line body is a feeding portion for a high-frequency signal of a waveguide path by the waveguide, and
the ground portion of the transmission line body is a part of the waveguide.

10. The semiconductor module according to claim 1, wherein
the transmission line body is a waveguide,
the waveguide comprises a conductor having an upper wall, a lower wall, both side walls, and a first end wall,
a space surrounded by inner faces of the upper wall, the lower wall, both of the side walls, and the first end wall forms a waveguide path in which a first end is short-circuited and a second end is opened,
the signal transmission portion of the transmission line body is a feeding portion for a high-frequency signal of the waveguide path,
the fixed portion of the signal connection terminal is inserted in a terminal insertion hole in the upper wall of the waveguide formed at a position corresponding to the feeding portion for the high-frequency signal of the waveguide path, a portion, of the fixed portion inserted inside the waveguide path, functioning as a feeding pin to feed, to the feeding portion, the high-frequency signal of the waveguide path, and
the ground portion of the transmission line body is a periphery of the upper wall of the waveguide surrounding the signal connection terminal.

11. The semiconductor module according to claim 1, wherein
the transmission line body is a waveguide having a conductor side wall and a conductor upper wall,
the conductor side wall comprises a conductor having both side walls and a first end wall, bottom faces of both of the side walls and the first end wall being in close contact with the front face of the heat dissipation plate,
the conductor upper wall comprises an upper wall substrate made of a dielectric and a ground conductor on each of a front face and a back face of the upper wall substrate,
a space surrounded by inner faces of both of the side walls and the first end wall of the conductor side wall, the ground conductor on the back face of the upper wall substrate, and the front face of the heat dissipation plate forms a waveguide path in which a first end is short-circuited and a second end is opened,
the signal transmission portion of the transmission line body is a feeding portion for a high-frequency signal of the waveguide path,
the fixed portion of the signal connection terminal is inserted in a terminal insertion hole in the conductor upper wall formed at a position corresponding to the feeding portion for the high-frequency signal of the waveguide path, a portion, of the fixed portion inserted inside the waveguide path, functioning as a feeding pin to feed, to the feeding portion, the high-frequency signal of the waveguide path, and
the ground portion of the transmission line body is a periphery of the ground conductor on the front face of the upper wall substrate surrounding the signal connection terminal.

12. The semiconductor module according to claim 1, wherein
the heat dissipation plate is a metal plate having a waveguide groove on a front face,
the transmission line body comprises a conductor upper wall,
the conductor upper wall comprises an upper wall substrate made of a dielectric and a ground conductor on each of a front face and a back face of the upper wall substrate, the conductor upper wall covering the waveguide groove of the heat dissipation plate, the ground conductor on the back face of the upper wall substrate being in close contact with the front face of the heat dissipation plate,
a space surrounded by the ground conductor on the back face of the upper wall substrate and the waveguide groove of the heat dissipation plate forms a waveguide path in which a first end is short-circuited and a second end is opened,
the signal transmission portion of the transmission line body is a feeding portion for a high-frequency signal of the waveguide path,
the fixed portion of the signal connection terminal is inserted in a terminal insertion hole in the conductor upper wall formed at a position corresponding to the feeding portion for the high-frequency signal of the waveguide path, and a portion, of the fixed portion inserted inside the waveguide path, functioning as a feeding pin to feed, to the feeding portion, the high-frequency signal of the waveguide path, and
the ground portion of the transmission line body is a periphery of the ground conductor on the front face of the upper wall substrate surrounding the signal connection terminal.

13. The semiconductor module according to claim 1, wherein
the transmission line body is a dielectric substrate integrated waveguide path having a side wall body and a conductor upper wall,
the side wall body comprises a dielectric substrate having a cutout portion having a second end opened, a ground conductor formed on each of a front face and a back face of the dielectric substrate, and a plurality of vias arranged around the cutout portion of the dielectric substrate to surround the cutout portion, each of the vias penetrating from the front face to the back face of the dielectric substrate to electrically connect the ground conductors on the front face and the back face of the dielectric substrate, and functioning as a pseudo conductor wall,
the conductor upper wall comprises an upper wall substrate made of a dielectric and a ground conductor on each of a front face and a back face of the upper wall substrate, the conductor upper wall covering the cutout portion of the side wall body, the ground conductor on the back face of the upper wall substrate being in close contact with the ground conductor on the front face of the side wall body,
a region surrounded by the ground conductor on the back face of the upper wall substrate and the plurality of vias of the side wall body forms a waveguide path in which a first end is short-circuited and a second end is opened,
the signal transmission portion of the transmission line body is a feeding portion for a high-frequency signal of the waveguide path,
the fixed portion of the signal connection terminal is inserted in a terminal insertion hole in the conductor upper wall formed at a position corresponding to a feeding portion for the high-frequency signal of the waveguide path, a portion, of the fixed portion inserted inside the waveguide path, functioning as a feeding pin to feed, to the feeding portion, the high-frequency signal of the waveguide path, and
the ground portion of the transmission line body is a periphery of the ground conductor on the front face of the upper wall substrate surrounding the signal connection terminal.

14. The semiconductor module according to claim 10, wherein
the waveguide path has a constant width from the first end to the open end.

15. The semiconductor module according to claim 10, wherein
the waveguide path has a tapered portion or a stepped portion that becomes narrow from the first end and has a constant width continuously from the tapered portion or the stepped portion to the open end.

16. The semiconductor module according to claim 10, further comprising a conductor plate attached to the portion of the fixed portion of the signal connection terminal inserted inside the waveguide path.

17. The semiconductor module according to claim 10, further comprising a metal column having a distal end positioned inside the waveguide path and facing the fixed portion of the signal connection terminal, the metal column attached to the heat dissipation plate.

18. The semiconductor module according to claim 1, wherein
the semiconductor element comprises a first high-frequency power-amplification semiconductor element to a fourth high-frequency power-amplification semiconductor element each having a signal terminal and a ground terminal on a front face,
in the interposer substrate, the semiconductor-element signal pad comprises a first amplified-signal input-side pad to a fourth amplified-signal input-side pad corresponding to the signal terminals of the first high-frequency power-amplification semiconductor element to the fourth high-frequency power-amplification semiconductor element, respectively, the transmission-line-body signal pad includes a first amplified-signal output-side pad and a second amplified-signal output-side pad, the interposer substrate comprising a first synthesis signal line connecting the first amplified-signal input-side pad and the second amplified-signal input-side pad with the first amplified-signal output-side pad and a second synthesis signal line connecting the third amplified-signal input-side pad and the fourth amplified-signal input-side pad with the second amplified-signal output-side pad,
the signal connection terminal comprises a first signal connection terminal having a movable portion in contact with and electrically connected to the first amplified-signal output-side pad of the interposer substrate, and a second signal connection terminal having a movable portion in contact with and electrically connected to the second amplified-signal output-side pad of the interposer substrate, and
in the transmission line body, the signal transmission portion comprises a first signal input portion to which a fixed portion of the first signal connection terminal is electrically connected and a second signal input portion to which a fixed portion of the second signal connection terminal is electrically connected, the transmission line body comprising a synthesis path that combines a high-frequency signal input to the first signal input portion and a high-frequency signal input to the second signal input portion.

19. The semiconductor module according to claim 18, wherein
the transmission line body is a waveguide,
the waveguide comprises a conductor having an upper wall, a lower wall, both side walls, and a first end wall,
the synthesis path comprises a first waveguide path having a first end short-circuited, a second waveguide path having a first end short-circuited, and a synthesis waveguide path having a first end communicating with a second end of the first waveguide path and a second end of the second waveguide path and having a second end opened, the first waveguide path, the second waveguide path, and the synthesis waveguide path formed in a space surrounded by inner faces of the upper wall, the lower wall, both of the side walls, and the first end wall,
the first signal input portion in the signal transmission portion of the transmission line body is a feeding portion for a high-frequency signal of the first waveguide path,
the second signal input portion in the signal transmission portion of the transmission line body is a feeding portion for a high-frequency signal of the second waveguide path,
the fixed portion of the first signal connection terminal in the signal connection terminal is inserted in a first terminal insertion hole in the upper wall of the waveguide formed at a position corresponding to the feeding portion for the high-frequency signal of the first waveguide path, a portion, of the fixed portion inserted inside the first waveguide path, functioning as a feeding pin to feed, to the feeding portion, the high-frequency signal of the first waveguide path,
the fixed portion of the second signal connection terminal in the signal connection terminal is inserted in a second terminal insertion hole in the upper wall of the waveguide formed at a position corresponding to the feeding portion for the high-frequency signal of the second waveguide path, a portion, of the fixed portion inserted inside the second waveguide path, functioning as a feeding pin to feed, to the feeding portion, the high-frequency signal of the second waveguide path, and
the ground portion of the transmission line body is a periphery of the upper wall of the waveguide surrounding each of the first signal connection terminal and the second signal connection terminal in the signal connection terminal.

20. The semiconductor module according to claim 18, wherein
the transmission line body is a waveguide having a conductor side wall and a conductor upper wall,
the conductor side wall comprises a conductor having both side walls and a first end wall, bottom faces of both of the side walls and the first end wall being in close contact with the front face of the heat dissipation plate,
the conductor upper wall comprises an upper wall substrate made of a dielectric and a ground conductor on each of a front face and a back face of the upper wall substrate,
the synthesis path comprises a first waveguide path having a first end short-circuited, a second waveguide path having a first end short-circuited, and a synthesis waveguide path having a first end communicating with a second end of the first waveguide path and a second end of the second waveguide path and having a second end opened, the first waveguide path, the second waveguide path, and the synthesis waveguide path formed in a space surrounded by inner faces of both side walls and the first end wall of the conductor side wall, the ground conductor on the back face of the upper wall substrate, and the front face of the heat dissipation plate,
the first signal input portion in the signal transmission portion of the transmission line body is a feeding portion for a high-frequency signal of the first waveguide path,
the second signal input portion in the signal transmission portion of the transmission line body is a feeding portion for a high-frequency signal of the second waveguide path,
the fixed portion of the first signal connection terminal in the signal connection terminal is inserted in a first terminal insertion hole in the upper wall of the waveguide formed at a position corresponding to the feeding portion for the high-frequency signal of the first waveguide path, a portion, of the fixed portion inserted inside the first waveguide path, functioning as a feeding pin to feed, to the feeding portion, the high-frequency signal of the first waveguide path,
the fixed portion of the second signal connection terminal in the signal connection terminal is inserted in a second terminal insertion hole in the upper wall of the waveguide formed at a position corresponding to the feeding portion for the high-frequency signal of the second waveguide path, a portion, of the fixed portion inserted inside the second waveguide path, functioning as a feeding pin to feed, to the feeding portion, the high-frequency signal of the second waveguide path, and
the ground portion of the transmission line body is a periphery of the ground conductor on the front face of the upper wall substrate surrounding each of the first signal connection terminal and the second signal connection terminal in the signal connection terminal.

21. The semiconductor module according to claim 18, wherein
the heat dissipation plate is a metal plate having a waveguide groove on a front face,
the transmission line body comprises a conductor upper wall,
the conductor upper wall comprises an upper wall substrate made of a dielectric and a ground conductor on each of a front face and a back face of the upper wall substrate, the conductor upper wall covering the waveguide groove of the heat dissipation plate, the ground conductor on the back face of the upper wall substrate being in close contact with the front face of the heat dissipation plate,
the synthesis path comprises a first waveguide path having a first end short-circuited, a second waveguide path having a first end short-circuited, and a synthesis waveguide path having a first end communicating with a second end of the first waveguide path and a second end of the second waveguide path and having a second end opened, the first waveguide path, the second waveguide path, and the synthesis waveguide path formed in a space surrounded by the ground conductor on the back face of the upper wall substrate and the waveguide groove of the heat dissipation plate,
the first signal input portion in the signal transmission portion of the transmission line body is a feeding portion for a high-frequency signal of the first waveguide path,
the second signal input portion in the signal transmission portion of the transmission line body is a feeding portion for a high-frequency signal of the second waveguide path,
the fixed portion of the first signal connection terminal in the signal connection terminal is inserted in a first terminal insertion hole in the conductor upper wall formed at a position corresponding to the feeding portion for the high-frequency signal of the first waveguide path, a portion, of the fixed portion inserted inside the first waveguide path, functioning as a feeding pin to feed, to the feeding portion, the high-frequency signal of the first waveguide path,
the fixed portion of the second signal connection terminal in the signal connection terminal is inserted in a second terminal insertion hole in the conductor upper wall formed at a position corresponding to the feeding portion for the high-frequency signal of the second waveguide path, a portion, of the fixed portion inserted inside the second waveguide path, functioning as a feeding pin to feed, to the feeding portion, the high-frequency signal of the second waveguide path, and
the ground portion of the transmission line body is a periphery of the ground conductor on the front face of the upper wall substrate surrounding each of the first signal connection terminal and the second signal connection terminal in the signal connection terminal.

22. The semiconductor module according to claim 18, wherein
the transmission line body is a dielectric substrate integrated waveguide having a side wall body and a conductor upper wall,
the side wall body comprises a dielectric substrate having a cutout portion having a second end opened, a ground conductor formed on each of a front face and a back face of the dielectric substrate, and a plurality of vias arranged around the cutout portion of the dielectric substrate to surround the cutout portion, each of the vias penetrating from the front face to the back face of the dielectric substrate to electrically connect the ground conductors on the front face and the back face of the dielectric substrate, and functioning as a pseudo conductor wall,
the conductor upper wall comprises an upper wall substrate made of a dielectric and a ground conductor on each of a front face and a back face of the upper wall substrate, the conductor upper wall covering the cutout portion of the side wall body, the ground conductor on the back face of the upper wall substrate being in close contact with the ground conductor on the front face of the side wall body,
the synthesis path comprises a first waveguide path having a first end short-circuited, a second waveguide path having a first end short-circuited, and a synthesis waveguide path having a first end communicating with a second end of the first waveguide path and a second end of the second waveguide path and having a second end opened, the first waveguide path, the second waveguide path, and the synthesis waveguide path formed in a region surrounded by the ground conductor on the back face of the upper wall substrate and the plurality of vias in the side wall body,
the first signal input portion in the signal transmission portion of the transmission line body is a feeding portion for a high-frequency signal of the first waveguide path,
the second signal input portion in the signal transmission portion of the transmission line body is a feeding portion for a high-frequency signal of the second waveguide path,
the fixed portion of the first signal connection terminal in the signal connection terminal is inserted in a first terminal insertion hole in the conductor upper wall formed at a position corresponding to the feeding portion for the high-frequency signal of the first waveguide path, a portion, of the fixed portion inserted inside the first waveguide path, functioning as a feeding pin to feed, to the feeding portion, the high-frequency signal of the first waveguide path,
the fixed portion of the second signal connection terminal in the signal connection terminal is inserted in a second terminal insertion hole in the conductor upper wall formed at a position corresponding to the feeding portion for the high-frequency signal of the second waveguide path, a portion, of the fixed portion inserted inside the second waveguide path, functioning as a feeding pin to feed, to the feeding portion, the high-frequency signal of the second waveguide path, and
the ground portion of the transmission line body is a periphery of the ground conductor on the front face of the upper wall substrate surrounding each of the first signal connection terminal and the second signal connection terminal in the signal connection terminal.

23. The semiconductor module according to claim 18, wherein
each of the first waveguide path, the second waveguide path, and the synthesis waveguide path in the synthesis path has a constant width from the first end to the second end.

24. The semiconductor module according to claim 18, wherein
each of the first waveguide path and the second waveguide path in the synthesis path has a tapered portion or a stepped portion that becomes narrow from the first end and has a constant width continuously from the tapered portion or the stepped portion to the second end, and the synthesis waveguide path in the synthesis path has a constant width from the first end to the second end.

25. The semiconductor module according to claim 19, further comprising:
a first conductor plate attached to the portion of the fixed portion of the first signal connection terminal in the signal connection terminal, the portion inserted inside the first waveguide path in the synthesis path; and
a second conductor plate attached to the portion of the fixed portion of the second signal connection terminal in the signal connection terminal, the portion inserted inside the second waveguide path in the synthesis path.

26. The semiconductor module according to claim 19, further comprising:
a first metal column having a distal end positioned inside the first waveguide path in the synthesis path, the first metal column facing the fixed portion of the first signal connection terminal in the signal connection terminal, the first metal column attached to the heat dissipation plate; and
a second metal column having a distal end positioned inside a second waveguide path in the synthesis path, the second metal column facing the fixed portion of the second signal connection terminal in the signal connection terminal, the second metal column attached to the heat dissipation plate.
